(19) United States
(12) Patent Application Publication
(10) Pub. No.: US 2024/0397765 A1
(43) Pub. Date: Nov. 28, 2024

(54) DISPLAY DEVICE

(71) Applicant: Samsung Display Co., LTD., Yongin-si (KR)

(72) Inventors: Jae Woong YOO, Yongin-si (KR); Sang Ho PARK, Yongin-si (KR); Jin Hyuk JANG, Yongin-si (KR); Sang Ho JEON, Yongin-si (KR)

(73) Assignee: Samsung Display Co., LTD., Yongin-si (KR)

(21) Appl. No.: 18/402,054

(22) Filed: Jan. 2, 2024

(30) Foreign Application Priority Data
May 26, 2023 (KR) 10-2023-0068712

(51) Int. Cl. H10K 59/131; H10K 59/123; H10K 59/32; H10K 102/10

(52) U.S. Cl. CPC H10K 59/131; H10K 59/123; H10K 59/32; H10K 2102/103

(57) ABSTRACT

A display device includes a first lower electrode disposed on a substrate, a first light emitting element disposed on the first lower electrode, a second electrode disposed on the first light emitting element, a second light emitting element disposed on the second electrode, and a first upper electrode disposed on the second light emitting element. The first lower electrode and the first upper electrode are connected to each other.

### CROSS-REFERENCE TO RELATED APPLICATION(S)

This application claims priority to and benefits of Korean Patent Application No. 10-2023-0068712 under 35 U.S.C. 119, filed on May 26, 2023, in the Korean Intellectual Property Office (KIPO), the entire contents of which are incorporated herein by reference.

### BACKGROUND

### 1. Technical Field

The disclosure relates to a display device.

### 2. Description of the Related Art

Display devices are becoming increasingly important with the development of multimedia. In response to this, various types of display devices, such as organic light emitting displays (OLED) and liquid crystal displays (LCD), are being used.

A device for displaying an image of a display device includes a display panel such as an organic light emitting display panel or a liquid crystal display panel. Among them, the light emitting display panel may include a light emitting element. For example, light emitting diodes (LED) include organic light emitting diodes (OLED) that utilize organic materials as light emitting materials, inorganic light emitting diodes that utilize inorganic materials as light emitting materials, and the like.

### SUMMARY

Aspects and features of embodiments of the disclosure provide a display device capable of low-current driving and having improved luminance.

However, aspects of the disclosure are not restricted to the one set forth herein and will become more apparent to one of ordinary skill in the art to which the disclosure pertains by referencing the detailed description of the disclosure given below.

According to an embodiment, a display device may include a first lower electrode disposed on a substrate, a first light emitting element disposed on the first lower electrode, a second electrode disposed on the first light emitting element, a second light emitting element disposed on the second electrode, and a first upper electrode disposed on the second light emitting element. The first lower electrode and the first upper electrode may be connected to each other.

The display device may further include a first planarization layer disposed on the substrate on which the first light emitting element is not disposed, and a second planarization layer disposed on the first planarization layer on which the second light emitting element is not disposed. The first lower electrode and the first upper electrode may be connected through a contact hole penetrating the first planarization layer and the second planarization layer.

The substrate may include a pixel circuit. The first lower electrode and the first upper electrode may be connected to the pixel circuit.

The first light emitting element and the second light emitting element may be connected in parallel.

The first light emitting element and the second light emitting element may be arranged in opposite directions.

The first light emitting element may include a first semiconductor layer, an active layer, and a second semiconductor layer sequentially stacked on the first lower electrode, and the second light emitting element may include a second semiconductor layer, an active layer, and a first semiconductor layer sequentially stacked on the second electrode.

A surface of the second electrode may be in contact with the second semiconductor layer of the first light emitting element, and another surface of the second electrode may be in contact with the second semiconductor layer of the second light emitting element.

The first light emitting element may further include a connection electrode between the first lower electrode and the first semiconductor layer, and the second light emitting element may further include a connection electrode between the first semiconductor layer and the first upper electrode.

The first upper electrode may include a transparent or translucent electrode including at least one of indium tin oxide (ITO), indium zinc oxide (IZO), Zinc Oxide (ZnO), Indium, Oxide (In2O3), Indium Gallium Oxide (IGO), and Aluminum Zinc Oxide (AZO).

The second electrode may include a transparent or translucent electrode including at least one of indium tin oxide (ITO), indium zinc oxide (IZO), Zinc Oxide (ZnO), Indium, Oxide (In2O3), Indium Gallium Oxide (IGO), and Aluminum Zinc Oxide (AZO).

The first light emitting element and the second light emitting element may overlap with each other in a thickness direction.

The substrate may include a pixel circuit, and the second electrode may pass through the first planarization layer and may be connected to the pixel circuit.

The first light emitting element may include a second semiconductor layer, an active layer, and a first semiconductor layer sequentially stacked on the first lower electrode, and the second light emitting element may include a first semiconductor layer, an active layer, and a second semiconductor layer sequentially stacked on the second electrode.

According to an embodiment, a display device may include a first lower electrode disposed on a substrate, a first light emitting element disposed on the first lower electrode, a second lower electrode disposed on the first light emitting element, an insulating layer disposed on the second lower electrode, a first upper electrode disposed on the insulating layer, a second light emitting element disposed on the first upper electrode, and a second upper electrode disposed on the second light emitting element. The first lower electrode and the first upper electrode may be connected to each other, and the second lower electrode and the second upper electrode may be connected to each other.

The display device may further include a first planarization layer disposed on the substrate on which the first light emitting element is not disposed, and a second planarization layer disposed on the insulating layer on which the second light emitting element is not disposed. The first lower electrode and the first upper electrode may be connected through a contact hole penetrating the first planarization layer and the insulating layer, and the second lower electrode and the second upper electrode may be connected through a second contact hole penetrating the second planarization layer and the second insulating layer.

The first light emitting element and the second light emitting element may be connected in series.

According to an embodiment, a display device may include a first lower electrode disposed on a substrate, a first light emitting element disposed on the first lower electrode, a second lower electrode disposed on the first light emitting element, a second light emitting element disposed on the second lower electrode, a first upper electrode disposed on the second light emitting element, a third light emitting element disposed on the first upper electrode, and a second upper electrode disposed on the third light emitting element. The first lower electrode and the first upper electrode may be connected to each other, and the second lower electrode and the second upper electrode may be connected to each other.

The display device may further include a first planarization layer disposed on the substrate on which the first light emitting element is not disposed, a second planarization layer disposed on the first planarization layer on which the second light emitting element is not disposed, and a third planarization layer disposed on the second planarization layer on which the third light emitting element is not disposed. The first lower electrode and the first upper electrode may be connected through a contact hole penetrating the first planarization layer and the second planarization layer, and the second lower electrode and the second upper electrode may be connected through a second contact hole penetrating the third planarization layer and the second planarization layer.

The first light emitting element, the second light emitting element, and the third light emitting element may be connected in parallel.

The first light emitting element may include a first semiconductor layer, an active layer, and a second semiconductor layer sequentially stacked on the first lower electrode, the second light emitting element may include a second semiconductor layer, an active layer, and a first semiconductor layer sequentially stacked on the second lower electrode, and the third light emitting element may include a first semiconductor layer, an active layer, and a second semiconductor layer sequentially stacked on the first upper electrode.

The display device according to embodiments may include multiple layers of light emitting elements and may share pixel electrodes and common electrodes of the multiple layers of light emitting elements.

In addition, low-current driving is possible, and luminance may be improved by connecting light emitting elements in parallel.

Furthermore, dark spots caused by defective or misaligned light emitting elements may be eliminated by forming light emitting elements in multiple layers in the same light emitting area.

However, the effects of the disclosure are not limited to the aforementioned effects, and various other effects are included in the specification.

### BRIEF DESCRIPTION OF THE DRAWINGS

FIG. 1 is a plan view of a display device according to an embodiment.

FIG. 2 is a schematic layout view of a circuit of a display substrate of a display device according to an embodiment.

FIG. 3 is a schematic diagram of an equivalent circuit of a pixel of a display device according to an embodiment.

FIG. 4 is a schematic diagram of an equivalent circuit of a pixel of a display device according to another embodiment.

FIG. 5 is a schematic diagram of an equivalent circuit of a pixel of a display device according to another embodiment.

FIG. 6 is a schematic cross-sectional view of a pixel of a display substrate, according to an embodiment.

FIG. 7 is an enlarged view of region B of FIG. 6, according to an embodiment.

FIG. 8 is an enlarged view of another side of a pixel of a display substrate.

FIGS. 9 to 31 are schematic diagrams for explaining a method of manufacturing a display device according to an embodiment.

FIG. 32 is a graph illustrating external quantum efficiency as a function of applied current density for parallel-connected light emitting elements according to an embodiment of the disclosure.

FIGS. 33 and 34 are schematic cross-sectional views of a display substrate according to an embodiment of the disclosure.

FIGS. 35 to 40 are schematic cross-sectional views of a display substrate according to another embodiment.

FIG. 41 is a perspective view of a virtual reality device including a display device according to an embodiment.

FIG. 42 is a perspective view of a smart device including a display device according to an embodiment.

FIG. 43 is a perspective view of a vehicle including a display device according to an embodiment.

FIG. 44 is a perspective view of a transparent display device including a display device according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers or symbols indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the disclosure will be described in detail with reference to the accompanying drawings.

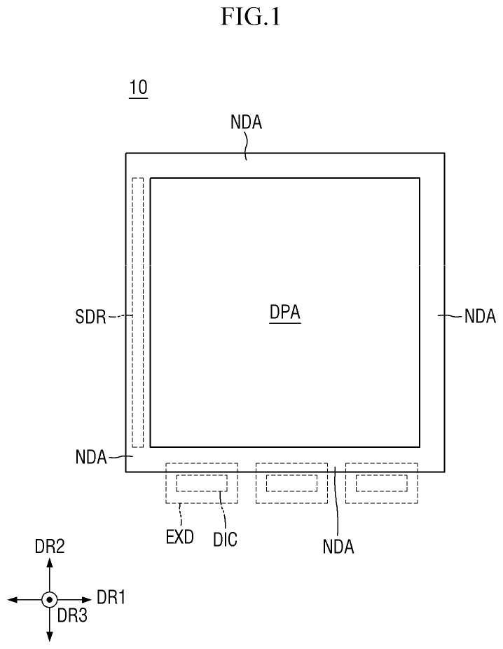

FIG. 1 is a plan view of a display device according to an embodiment.

Referring to FIG. 1, a display device 10 according to an embodiment may be applied to various consumer electronics, such as smartphones, cell phones, tablet PC, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, and washing machines, and the like, or internet of things devices. A television is described herein as an embodiment of the display device, and the television may have a high or ultra-high resolution, such as HD, UHD, 4K, 8K, etc.

Furthermore, the display device 10 according to embodiments may be variously categorized based on how it is displayed. For example, the display device may be an organic light emitting display device (OLED), an inorganic light emitting display device (inorganic EL), a quantum dot light emitting display device (QED), a micro-LED display device (micro-LED), a nano-LED display device (nano-LED), a plasma display device (PDP), a field emission display device (FED), a cathode ray display device (CRT), a liquid crystal display device (LCD), an electrophoretic display device (EPD), or the like. In the following, the organic light emitting display device will be described as an embodiment of a display device, and the organic light emitting display device applied in an embodiment will be abbreviated simply as a display device unless otherwise indicated. However, the disclosure is not limited to organic light emitting display device, and other display devices including display devices listed above, may be employed to the extent that they share technical ideas.

In the drawings, the first direction DR1 refers to a horizontal direction of the display device 10, the second direction DR2 refers to a vertical direction of the display device 10, and the third direction DR3 refers to a thickness direction of the display device 10. “Left”, “right”, “up”, and “down” refer to directions when the display device 10 is viewed from above (e.g., in a plan view). For example, “right” refers to a side of the first direction DR1, “left” refers to another side of the first direction DR1, “top” refers to a side of the second direction DR2, and “bottom” refers to another side of the second direction DR2. Further, “upper” refers to a first side of the third direction DR3 and “lower” refers to a second side of the third direction DR3.

The display device 10 according to an embodiment may have a square shape in a plan view. In case that the display device 10 is a television, the display device 10 may have a rectangular shape with the long sides disposed in the transverse direction. However, the disclosure is not limited thereto, and the long sides may be disposed in the longitudinal direction, or the display device 10 may be rotatably mounted so that the long sides are variably disposed in the horizontal or vertical direction. The display device 10 may have a circular or oval shape in a plan view.

The display device 10 may include a display area DPA and a non-display area NDA. The display area DPA may be an active area where an image is displayed. The display area DPA may have a square shape in plan view similar to the overall shape of the display device 10, but the disclosure is not limited thereto.

The non-display area NDA may be disposed on the periphery of the display area DPA. The non-display area NDA may fully or partially enclose the display area DPA in a plan view. The display area DPA may have a square shape in a plan view, and the non-display areas NDA may be arranged to be adjacent to the four sides of the display area DPA. The non-display area NDA may comprise a bezel of the display device 10.

A driving circuit or a driving element for driving the display area DPA may be disposed in the non-display area NDA. In an embodiment, the non-display area NDA disposed adjacent to the first side (lower side in FIG. 1) of the display device 10 may have a pad portion provided on the display substrate of the display device 10, and an external device EXD may be mounted on the pad electrode of the pad portion. Examples of the external device EXD include a connection film, a printed circuit board, a driving chip (DIC), a connector, a wiring connection film, and the like. In the non-display area NDA disposed adjacent to the second side (left side in FIG. 1) of the display device 10, a scan driving unit SDR, or the like formed (e.g., directly formed) on the display substrate of the display device 10 may be disposed.

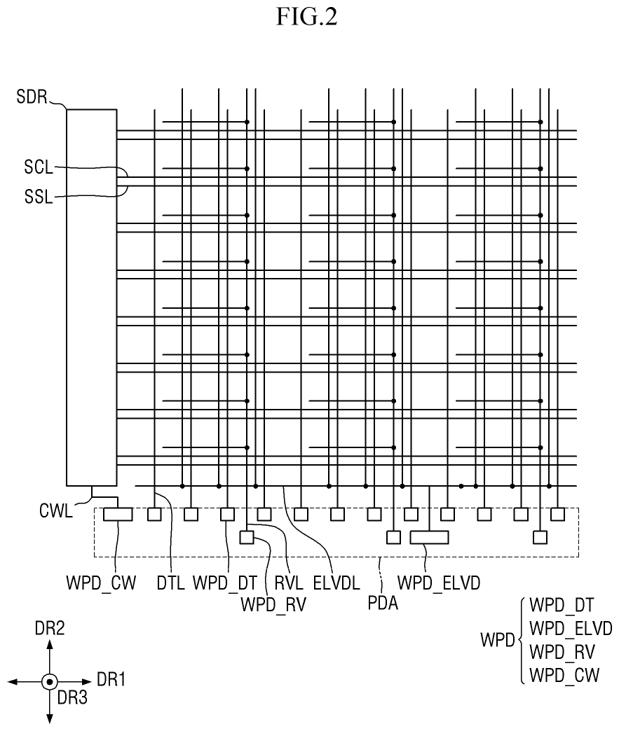

FIG. 2 is a schematic layout view of a circuit of a display substrate of a display device according to an embodiment.

Referring to FIG. 2, multiple lines may be disposed on the first substrate. The lines may include a scan line SCL, a sensing signal line SSL, a data line DTL, a reference voltage line RVL, a first power supply line ELVDL, and the like.

The scan line SCL and the sensing signal line SSL may be extended in the first direction DR1. The scan line SCL and the sensing signal line SSL may be connected to the scan driving unit SDR. The scan driving unit SDR may include a driving circuit. The scan driving unit SDR may be disposed on a side of the non-display area NDA on the display substrate, but the disclosure is not limited thereto, and the scan driving unit SDR may be disposed on both sides of the non-display area NDA. The scan driving unit SDR may be connected to a signal connection line CWL, and at least one end of the signal connection line CWL may be connected to an external device (“EXD” in FIG. 1) by forming a pad (WPD_CW) on the first non-display area NDA and/or the second non-display area NDA.

The data line DTL and the reference voltage line RVL may extend in the second direction DR2 intersecting the first direction DR1. The first power supply line ELVDL may include a portion extending in the second direction DR2. The first power supply line ELVDL may further include a portion extending in the first direction DR1. The first power supply line ELVDL may have a mesh structure, but the disclosure is not limited thereto.

Wiring pads WPD may be disposed at at least one end of the data line DTL, the reference voltage line RVL, and the first power supply line ELVDL. Each wiring pad WPD may be disposed on a pad area PDA of the non-display area (NDA). In an embodiment, a wiring pad WPD_DT (hereinafter also referred to as a “data pad”) for a data line DTL, a wiring pad WPD_RV (hereinafter also referred to as a “reference voltage pad”) for the reference voltage line RVL, and a wiring pad WPD_ELVD (hereinafter also referred to as a “first power pad”) for a first power supply line ELVDL may be disposed on the pad area PDA of the non-display area NDA. In another embodiment, the data pad WPD_DT, the reference voltage pad WPD_RV, and the first power supply pad WPD_ELVD may be disposed in different non-display areas NDA. An external device (“EXD” in FIG. 1) may be mounted on the wiring pad WPD as described above. The external device EXD may be mounted on the wiring pad WPD through an anisotropic conductive film, ultrasonic bonding, or the like.

Each pixel on the display board may include a pixel driving circuit (or pixel circuit). The wiring described above may pass through or around each pixel and apply a driving signal to each pixel driving circuit. The pixel driving circuit may include a transistor and a capacitor. The number of transistors and capacitors in each pixel driving circuit may vary. Hereinafter, the pixel driving circuit will be described taking a 3T1C structure including three transistors and one capacitor as an embodiment, but the disclosure is not limited thereto, and various other modified pixel structures such as a 2T1C structure, a 7T1C structure, and a 6T1C structure may be applied.

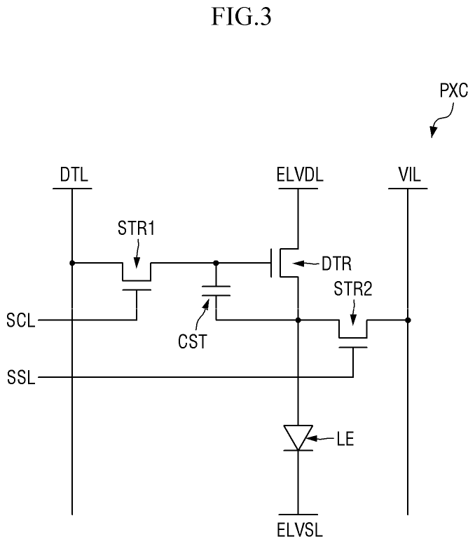

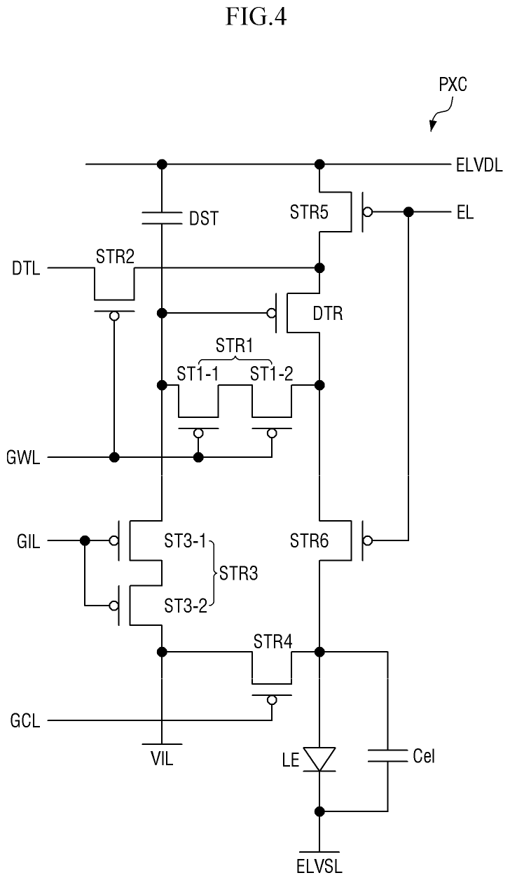

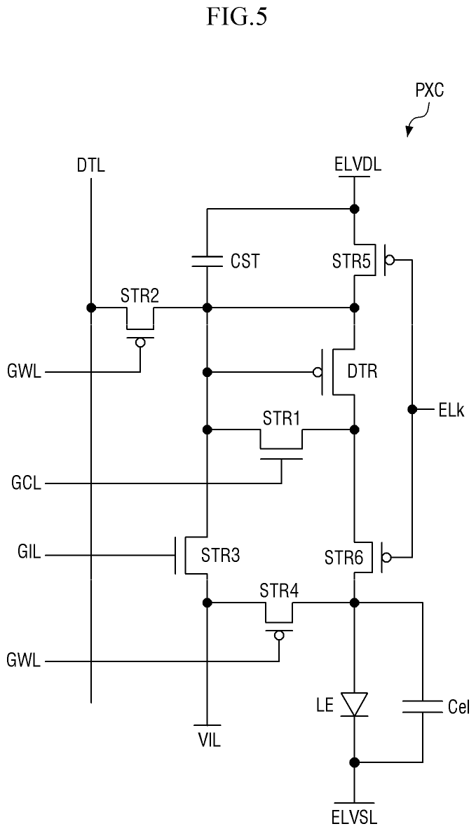

FIG. 3 is a schematic diagram of an equivalent circuit of a pixel of a display device according to an embodiment. FIG. 4 is a schematic diagram of an equivalent circuit of a pixel of a display device according to another embodiment. FIG. 5 is a schematic diagram of an equivalent circuit of a pixel of a display device according to another embodiment.

Referring to FIG. 3, a pixel circuit PXC according to an embodiment may include three transistors DTR, STR1, and STR2 and one capacitor for storage CST.

The light emitting element LE may emit light in response to a current supplied through a driving transistor DTR. The light emitting element LE may be an inorganic light emitting diode, an organic light emitting diode, a micro light emitting diode, a nano light emitting diode, or the like.

A first electrode (i.e., an anode electrode) of the light emitting element LE may be connected to a source electrode of the driving transistor DTR, and a second electrode (i.e., a cathode electrode) of the light emitting element LE may be connected to a second power supply line ELVSL supplied with a low potential voltage (second power supply voltage) lower than a high potential voltage (first power supply voltage) of the first power supply line ELVDL.

The driving transistor DTR may adjust the current flowing to the light emitting element LE from the first power supply line ELVDL supplied with the first power voltage according to the voltage difference between a gate electrode and the source electrode of the driving transistor DTR. The gate electrode of the driving transistor DTR may be connected to the first electrode of the first transistor ST1, the source electrode of the driving transistor DTR may be connected to the first electrode of the light emitting element LE, and a drain electrode of the driving transistor DTR may be connected to the first power supply line ELVDL to which the first power supply voltage is applied.

A first transistor STR1 may be turned-on by a scan signal from the scan line SCL to connect the data line DTL to the gate electrode of the driving transistor DTR. The gate electrode of the first transistor STR1 may be connected to the scan line SL, the first electrode of the first transistor STR1 may be connected to the gate electrode of the driving transistor DTR, and the second electrode of the first transistor STR1 may be connected to the data line DTL.

A second transistor STR2 may be turned-on by a sensing signal from the sensing signal line SSL to connect an initialization voltage line VIL to the source electrode of the driving transistor DTR. The gate electrode of the second transistor ST2 may be connected to the sensing signal line SSL, the first electrode of the second transistor ST2 may be connected to the initialization voltage line VIL, and the second electrode of the second transistor ST2 may be connected to the source electrode of the driving transistor DTR.

In an embodiment, the first electrode of each of the first and second transistors STR1 and STR2 may be a source electrode and the second electrode may be a drain electrode, but the disclosure is not limited to, and may be vice versa.

The capacitor CST may be formed between the gate and source electrodes of the driving transistor DTR. A storage capacitor CST may store the difference in voltage between the gate voltage of the driving transistor DTR and the source voltage of the driving transistor DTR.

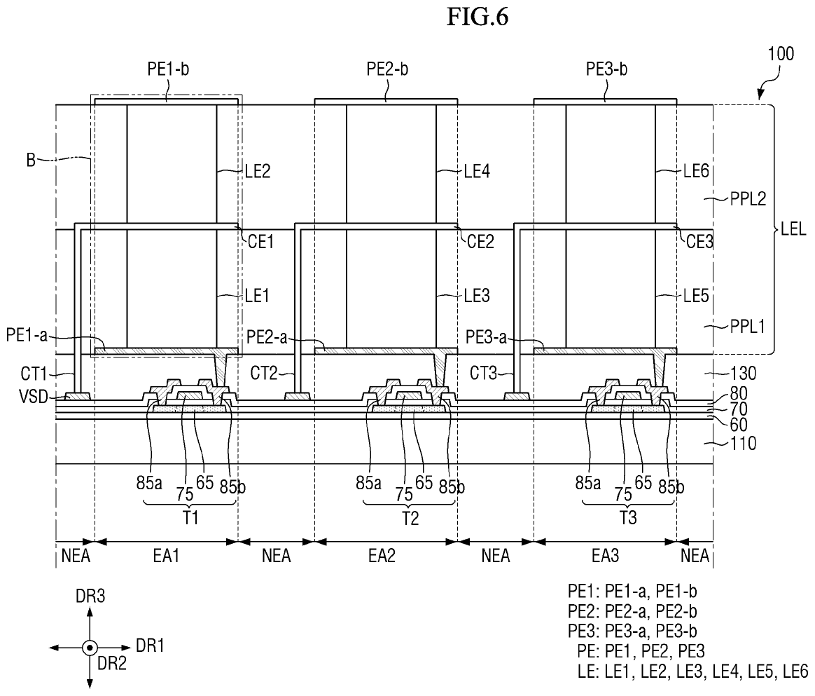

The driving transistor DTR and the first and second transistors STR1 and STR2 may be formed as thin film transistors. Although FIG. 6 describes the driving transistor DTR and the first and second switching transistors STR1 and STR2 as being N-type MOSFET (metal oxide semiconductor field effect transistors), the disclosure is not limited to thereto. For example, the driving transistor DTR and the first and second switching transistors STR1 and STR2 may be P-type MOSFET, or some may be N-type MOSFET, and others may be P-type MOSFET.

Referring to FIG. 4, the first electrode of the light emitting element LE of the pixel circuit PXC according to another embodiment may be connected to the first electrode of the fourth transistor STR4 and the second electrode of the sixth transistor STR6, and the second electrode of the light emitting element LE may be connected to the second power supply line ELVSL. A parasitic capacity Cel may be formed between the first electrode and the second electrode of the light emitting element LE.

Each pixel PX may include the driving transistor DTR, switch elements, and the capacitor CST. The switch elements may include first to sixth transistors STR1, STR2, STR3, STR4, STR5, and STR6.

The driving transistor DTR may include the gate electrode, the first electrode, and the second electrode. The driving transistor DTR may control the drain-to-source current Ids (hereinafter also referred to as the “driving current”) flowing between the first and second electrodes based on the data voltage applied to the gate electrode.

The capacitor CST may be formed between the second electrode of the driving transistor DTR and the second power supply line ELVSL. An electrode of the capacitor CST may be connected to the second electrode of the driving transistor DTR, and another electrode may be connected to the second power supply line ELVSL.

In case that the first electrode of each of the first to sixth transistors STR1, STR2, STR3, STR4, STR5, and STR6 and the driving transistor DTR is a source electrode, the second electrode may be a drain electrode. In another embodiment, in case that the first electrode of each of the first to sixth transistors STR1, STR2, STR3, STR4, STR5, and STR6 and the driving transistor DTR is a drain electrode, the second electrode may be a source electrode.

An active layer of each of the first to sixth transistors STR1, STR2, STR3, STR4, STR5, and STR6 and the driving transistor DTR may be formed from one of polysilicon, amorphous silicon, and oxide semiconductors. In case that the semiconductor layer of each of the first through sixth transistors STR1, STR2, STR3, STR4, STR5, and STR6 and the driving transistor DTR is formed from poly silicon, the process for forming the semiconductor layer of each of the first through sixth transistors STR1, STR2, STR3, STR4, STR5, and STR6 and the driving transistor DTR may be a low temperature poly silicon (LTPS) process.

In FIG. 5, the first to sixth transistors STR1, STR2, STR3, STR4, STR5, and STR6 and the driving transistor DTR are described as a P-type MOSFET (Metal Oxide Semiconductor Field Effect Transistor), but the disclosure is not limited thereto, and may be formed as an N-type MOSFET.

Further, the first power supply voltage of the first power supply line ELVDL, the second power supply voltage of the second power supply line ELVSL, and the third power supply voltage of the third power supply line VIL may be set by considering the characteristics of the driving transistor DTR, the characteristics of the light emitting element LE, and the like.

Referring to FIG. 5, the pixel circuit PXC according to another embodiment differs from the embodiment of FIG. 4 in that the driving transistor DTR, the second transistor STR2, the fourth transistor STR4, the fifth transistor STR5, and the sixth transistor STR6 are formed as a P-type MOSFET, and the first transistor STR1 and the third transistor STR3 are formed as an N-type MOSFET.

The active layer of each of the driving transistor DTR, second transistor STR2, fourth transistor STR4, fifth transistor STR5, and sixth transistor STR6 formed as the P-type MOSFET may be formed of polysilicon, and the active layer of each of the first transistor STR1 and third transistor STR3 formed as the N-type MOSFET may be formed of an oxide semiconductor.

FIG. 5 differs from the embodiment of FIG. 4 in that the gate electrode of the second transistor STR2 and the gate electrode of the fourth transistor STR4 are connected to the write scan line GWL, and the gate electrode of the first transistor ST1 is connected to the control scan ling GCL. Also, in FIG. 5, the first transistor STR1 and the third transistor STR3 are formed as an N-type MOSFET, so that the scan signal of the gate high voltage may be applied to the control scan line GCL and the initialization scan line GIL. On the other hand, since the second transistor STR2, the fourth transistor STR4, the fifth transistor STR5, and the sixth transistor STR6 are formed as a P-type MOSFET, the scan signal with a gate low voltage may be applied to the write scan wire GWL and the light emitting element LE.

It should be noted that the pixel circuit PXC is not limited to that shown in FIGS. 3 to 5. The pixel circuit PXC may be formed by other circuit structures that may be employed by those skilled in the art other than the embodiments shown in FIGS. 3 to 5.

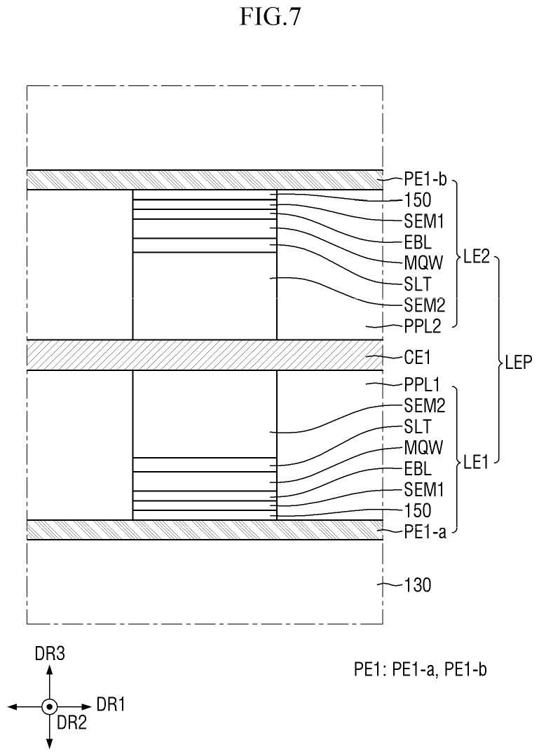

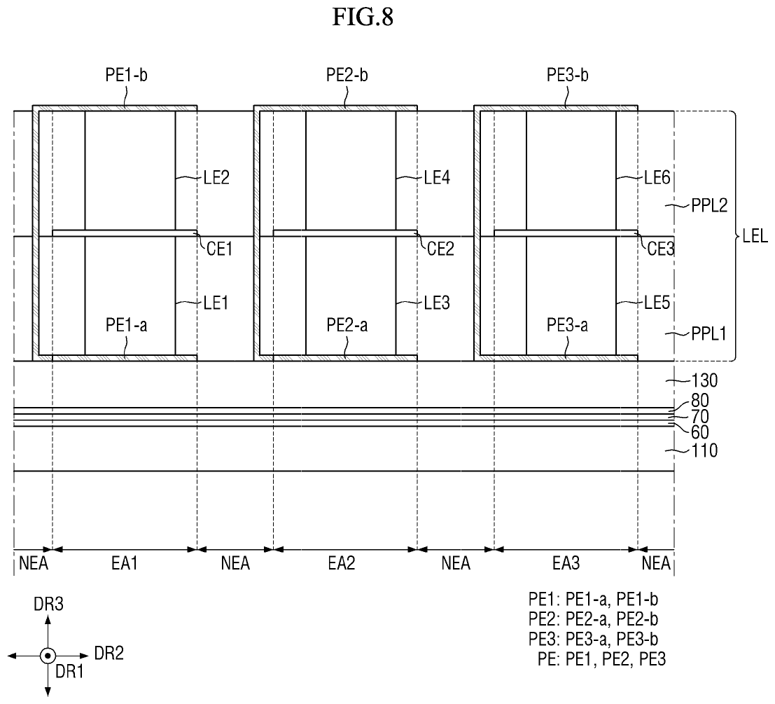

FIG. 6 is a schematic cross-sectional view of a pixel of a display substrate, according to an embodiment. FIG. 7 is an enlarged view of region B of FIG. 6, according to an embodiment. FIG. 8 is an enlarged view of a pixel of a display substrate.

Referring to FIGS. 6 to 8, the display area DPA may include multiple pixels. Each of the pixels may include multiple sub-pixels.

Each of the pixels may include a first sub-pixel, a second sub-pixel, and a third sub-pixel.

In each of the pixels, the first sub-pixel, the second sub-pixel, and the third sub-pixel may be arranged in a direction.

Each of the sub-pixels may include a pixel electrode PE1, PE2, and PE3, multiple light emitting elements LE, and a common electrode CE1, CE2, and CE3. The light emitting elements may be formed in multilayers. The multilayered light emitting elements may share a common electrode with the pixel electrodes. The sharing of the light emitting elements with the pixel electrodes and the common electrode will be described in more detail below.

The pixel electrodes PE1, PE2, and PE3 are illustrated as having a rectangular planar shape, but the disclosure is not limited thereto, and the pixel electrodes PE1, PE2, and PE3 may have polygonal or circular shapes such as triangles, pentagons, hexagons, and octagons.

Referring to FIG. 6, a display substrate 100 may include a first substrate 110 and a light emitting element layer LEL disposed on the first substrate 110. The first substrate 110 may be an insulating substrate. The first substrate 110 may include a transparent material. For example, the first substrate 110 may include a transparent insulating material such as glass, quartz, or the like. The first substrate 110 may be a rigid substrate but is not limited thereto. The first substrate 110 may include a plastic, such as polyimide, or the like, and may have flexible properties that allow the first substrate 110 to be warped, bent, folded, or rolled. Multiple light emitting areas EA1, EA2, and EA3 and non-emitting areas NEA may be defined on the first substrate 110.

Switching elements T1, T2, and T3 may be disposed on the first substrate 110. In an embodiment, a first switching element T1 may be disposed in the first light emitting area EA1 of the first substrate 110, a second switching element T2 may be disposed in the second light emitting area EA2, and a third switching element T3 may be disposed in the third light emitting area LA3. However, the disclosure is not limited thereto, and in other embodiments, at least one of the first switching element T1, the second switching element T2, and the third switching element T3 may be disposed in the non-emitting area NEA.

In an embodiment, the first switching element T1, the second switching element T2, and the third switching element T3 may each be a thin film transistor including an amorphous silicon, polysilicon, or an oxide semiconductor. Although not shown, multiple signal lines (e.g., gate lines, data lines, power supply lines, etc.) for transmitting signals to each switching element may be positioned on the first substrate 110.

Each switching element T1, T2, and T3 may include a semiconductor layer 65, a gate electrode 75, a source electrode 85a, and a drain electrode 85b. In an embodiment, a buffer layer 60 may be disposed on the first substrate 110. The buffer layer 60 may be disposed to cover a front (or an upper) side of the first substrate 110. The buffer layer 60 may include a silicon nitride, a silicon oxide, or a silicon oxynitride, and have a single layer or a double layers.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, or an oxide semiconductor. In an embodiment, the oxide semiconductor, for example, may include a binary compound (ABₓ), a ternary compound (ABₓC_{y}), or a tetracyclic compound (ABₓC_{y}D_{z}) including indium, zinc, gallium, tin, titanium, aluminum, hafnium (Hf), zirconium (Zr), magnesium (Mg), or the like. In an embodiment, the semiconductor layer 65 may include indium tin zinc oxide (IGZO).

A gate insulating layer 70 may be disposed on the semiconductor layer 65. The gate insulating layer 70 may include a silicon compound, a metal oxide, or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, or the like. In an embodiment, the gate insulating layer 70 may include a silicon oxide.

The gate electrode 75 may be disposed on the gate insulating layer 70. The gate electrode 75 may overlap the semiconductor layer 65 in a plan view. The gate electrode 75 may include a conductive material. The gate electrode 75 may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium, but the disclosure is not limited thereto.

An interlayer insulating layer 80 may be disposed on the gate electrode 75. The interlayer insulating layer 80 may include an inorganic insulating material such as a silicon oxide, a silicon nitride, a silicon oxynitride, a hafnium oxide, an aluminum oxide, a titanium oxide, a tantalum oxide, a zinc oxide, and the like.

The source electrode 85a and a drain electrode 85b may be disposed on the interlayer insulating layer 80. The source electrode 85a and the drain electrode 85b may contact the semiconductor layer 65 through contact holes penetrating the interlayer insulating layer 80 and the gate insulating layer 70, respectively. The source electrode 85a and the drain electrode 85b may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed of a Cu/Ti double layer in which an upper layer of copper is stacked on a lower layer of titanium but is not limited thereto.

An insulating layer 130 may be disposed on the first switching element T1, the second switching element T2, and the third switching element T3. In an embodiment, the insulating layer 130 may be a planarization layer and may include an organic material. For example, the insulating layer 130 may include an acrylic-based resin, an epoxy-based resin, an imide-based resin, an ester-based resin, or the like. In an embodiment, the insulating layer 130 may include a positively photosensitive material or a negatively photosensitive material.

The light emitting element layer LEL may be disposed on the insulating layer 130. The light emitting element layer LEL may include multiple pixel electrodes PE1, PE2, and PE3, multiple light emitting elements LE, and multiple common electrodes CE1 and CE2.

Each of the first light emitting area EA1, the second light emitting area EA2, and the third light emitting area EA3 may include parallel-connected light emitting elements LE. For example, the first light emitting area EA1 may include a first pixel electrode PE1, a first light emitting element LE1 and a second light emitting element LE2 connected in parallel, and the first common electrode CE1, the second light emitting area EA2 may include the second pixel electrode PE2, a third light emitting element LE3 and a fourth light emitting element LE4 connected in parallel, and the second common electrode CE2, and the third light emitting area EA3 may include the third pixel electrode PE3, a fifth light emitting element LE5 and a sixth light emitting element LE6 connected in parallel.

Referring to FIG. 7, for convenience of description, the pixel electrodes, the parallel-connected light emitting elements, and the common electrode included in one light emitting area are referred to as the light emitting element part LEP.

The first light emitting element LE1 may be a vertical light emitting diode element extending in the third direction DR3, for example, the length in the third direction DR3 of the light emitting element LE1 may be greater than the length in the horizontal direction. The length in the horizontal direction may be the length in the first direction DR1 or the length in the second direction DR2. For example, the length in the third direction DR3 of the light emitting element LE may be in a range of about 1nm to about 5 nm.

The first light emitting element LE1 may be a micro light emitting diode element. The light emitting element LE may include a connection electrode 150, a first semiconductor layer SEM1, an electronic blocking layer EBL, an active layer MQW, a superlattice layer SLT, and a second semiconductor layer SEM2. The connection electrode 150, the first semiconductor layer SEM1, the electronic blocking layer EBL, the active layer MQW, the superlattice layer SLT, and the second semiconductor layer SEM2 may be stacked sequentially in the third direction DR3.

The first light emitting element LE1 may have a cylindrical, disk, or rod shape with a width longer than a height. However, the disclosure is not limited thereto, and the light emitting element LE may have a shape such as a rod, wire, tube, etc., a polygonal shape such as a cube, a rectangle, a hexagonal column, or a shape extending in a direction but having a partially inclined outer surface. Although the first light emitting element LE1 has been described above, a second light emitting element LE2, the third light emitting element LE3, the fourth light emitting element LE4, the fifth light emitting element LE5, and the sixth light emitting element LE6 may be identical to the first light emitting element LE1, so each description is omitted.

The connection electrode 150 may serve to apply a light emitting signal to the first light emitting element LE1 by bonding with the first pixel electrode PE1. The first light emitting element LE1 may include at least one connection electrode 150. FIG. 7 illustrates that one connection electrode 150 is included, but the disclosure is not limited thereto. In another embodiment, the light emitting element LE may include more than one connection electrode 150 or may be omitted. The description of the light emitting element LE to be described below may be equally applied even in case that the number of connection electrodes 150 is changed or other structures are further included.

The connection electrode 150 may reduce the resistance between the light emitting element LE and the contact electrode in case that the light emitting element LE is electrically connected to the first pixel electrode PE1 in the display substrate 100 according to an embodiment. The connection electrode 150 may include a conductive metal. For example, the connection electrode 150 may include at least one of gold (Au), copper (Cu), tin (Sn), titanium (Ti), aluminum (Al), and silver (Ag). For example, the connection electrode 150 may include a 9:1 alloy of gold and tin, an 8:2 alloy, or a 7:3 alloy, or may include an alloy of copper, silver, and tin (SAC305).

Although not shown, an additional ohmic contact layer may be disposed on the connection electrode 150. The ohmic contact layer may be disposed between the connection electrode 150 and the first semiconductor layer SEM1. The ohmic contact layer may be an ohmic connection electrode. However, the disclosure is not limited thereto, and a Schottky connection electrode may be disposed on the connection electrode 150. The ohmic contact layer may include ITO. However, the disclosure is not limited thereto, and the ohmic contact layer may include at least one of gold (Au), copper (Cu), tin (Sn), titanium (Ti), aluminum (Al), silver (Ag), an alloy thereof, and a multilayer structure thereof.

The first semiconductor layer SEM1 may be disposed on the connection electrode 150. The first semiconductor layer SEM1 may be a p-type semiconductor and may include a semiconductor material having a chemical formula of AlₓGa_{y}In_{1-x-y}N (0≤x≤1, 0≤y≤1, 0≤x+y≤1). For example, the first semiconductor layer SEM1 may include at least one of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, and the like. For example, the first semiconductor layer SEM1 may be p-GaN doped with p-type Mg. The thickness of the first semiconductor layer SEM1 may be in a range of about 30 nm to about 200 nm, but the disclosure is not limited thereto.

The electronic blocking layer EBL may be disposed on the first semiconductor layer SEM1. The electronic blocking layer EBL may be a layer to suppress or prevent too many electrons from flowing into the active layer MQW. For example, the electronic blocking layer EBL may be p-AlGaN doped with p-type Mg. The thickness of the electronic blocking layer EBL may be in a range of about 10 nm to about 50 nm, but the disclosure is not limited thereto. In an embodiment, the electronic blocking layer EBL may be omitted.

The active layer MQW may be disposed on the electronic blocking layer EBL. The active layer MQW may emit light by coupling of electron-hole pairs in response to an electrical signal applied through the first semiconductor layer SEM1 and the second semiconductor layer SEM2. The active layer MQW may emit first light, for example, light of a blue wavelength band, or second light, for example, light of a green wavelength band.

The active layer MQW may include a single or multiple quantum well structure. In case that the active layer includes a material with a multi-quantum well structure, the active layer may have a stacked structure of multiple well layers and a barrier layer alternating with each other. The well layer may be formed of InGaN, and the barrier layer may be formed of GaN or AlGaN, but the disclosure is not limited thereto. The thickness of the well layer may be in a range of about 1 nm to about 4nm, and the thickness of the barrier layer may be in a range of about 3 nm to about 10nm.

In another embodiment, the active layer MQW may have a structure in which a semiconductor material having a large band gap energy and a semiconductor material having a small band gap energy are alternately stacked with each other and may include Group 3 to Group 5 semiconductor materials depending on the wavelength band of the emitted light. The light emitted by the active layer MQW is not limited to the first light, and in another embodiment, the second light (light of the green wavelength band) or the third light (light of the red wavelength band) may be emitted. In an embodiment, in case that indium is included in the active layer MQW, the color of emitted light may vary according to the content of indium. For example, light of the blue wavelength band may be emitted in case that the content of indium is about 15%, light of the green wavelength band may be emitted in case that the content of indium is about 25%, and light of the red wavelength band may be emitted in case that the content of indium is greater than or equal to about 35%.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN or GaN. A thickness of the superlattice layer SLT may be in a range of about 50 nm to about 200 nm. The superlattice layer SLT may be omitted.

The second semiconductor layer SEM2 may be disposed on the superlattice layer SLT1. The second semiconductor layer SEM2 may be a n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the second semiconductor layer SEM2 may include at least one of n-type doped AlGaInN, GaN, AlGaN, InGaN, AlN, and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness of the second semiconductor layer SEM2 may be in a range of about 2 μm to about 4 μm, but the disclosure is not limited thereto.

A first planarization layer PPL1 may be disposed on the pixel electrodes PE1, PE2, and PE3 and the insulating layer 130. The first planarization layer PPL1 may planarize lower step so that the first common electrode CE1 may be formed, as described below.

The first planarization layer PPL1 may include an organic material to planarize the lower step. For example, the first planarization layer PPL1 may include a polyacrylates resin, an epoxy resin, a phenolic resin, a polyamides resin, a polyimides rein, an unsaturated polyester resin, a poly phenylenethers resin, a polyphenylenesulfides resin, or benzocyclobutene (BCB).

Referring to FIGS. 6 and 7, the first common electrode CE1 may be disposed on the first planarization layer PPL1 and the first light emitting element LE1. For example, the first common electrode CE1 may be disposed on the first light emitting element LE1. The first common electrode CE1 may overlap each of the light emitting areas EA1, EA2, and EA3 in a plan view in the display area DPA, and may be made of a thin thickness so that light may be emitted.

The first common electrode CE1 may be disposed on (e.g., directly on) the first light emitting element LE1. For example, the first common electrode CE1 may be in contact with the second semiconductor layer SEM2 of the first light emitting element LE1 having a conductivity, so that a common voltage may be applied to each of the first light emitting elements LE1.

The first common electrode CE1 may be a cathode electrode in an embodiment. The first common electrode CE1 may include at least one of Li. Ca, LiF/Ca, LiF/Al, Al, Ag, and Mg in an embodiment. In an embodiment, the first common electrode CE1 may be formed of a thin metal film having a low work function. The first common electrode CE1 may be a transparent or translucent electrode including at least one of indium tin oxide (ITO), indium zinc oxide (IZO), Zinc Oxide (ZnO), Indium, Oxide (In₂O₃), Indium Gallium Oxide (IGO), and Aluminum Zinc Oxide (AZO) in an embodiment.

In the upper light emitting structure, the first common electrode CE1 may be formed from a transparent conductive oxide (TCO) such as indium tin oxide (ITO) and indium zinc oxide (IZO), which may transmit light, or a semi-transmissive conductive material such as magnesium (Mg), silver (Ag), or an alloy thereof. In case that the first common electrode CE1 is formed from the semi-transmissive conductive material, the light emission efficiency may be increased by micro cavities. The first common electrode CE1 may be connected to a common voltage pad VSD through the first planarization layer PPL1. The common voltage pad VSD may be connected to the second power supply line (ELVSL in FIGS. 3 to 5) through the common voltage pad VSD.

The second light emitting element LE2 may be disposed on the first common electrode CE1.

The second light emitting element LE2 may be stacked sequentially with the second semiconductor layer SEM2, the superlattice layer SLT, the active layer MQW, the electronic blocking layer EBL, the first semiconductor layer SEM1, and the connection electrode 150 in the third direction DR3 in a direction away from the first common electrode CE1. For example, the second light emitting element LE2 may be disposed in the opposite direction from the first light emitting element LE1.

A second planarization layer PPL2 may be disposed on the second light emitting element LE2 and the first planarization layer PPL1 on which the second light emitting element LE2 is not disposed. The second planarization layer PPL2 may planarize the step formed by the second light emitting element LE2 described below.

The second planarization layer PPL2 may include an organic material to planarize the lower step. For example, the second planarization layer PPL2 may include a polyacrylates resin, an epoxy resin, a phenolic resin, a polyamide resin, a polyimide rein, unsaturated polyester resin, a poly phenylenether resin, a polyphenylenesulfide resin, or benzocyclobutene (BCB). The second planarization layer PPL2 and the first planarization layer PPL1 may include a same material, but the disclosure is not limited to.

The connection electrode 150 of the second light emitting element LE2 may be in contact with the first electrode PE1.

The first pixel electrode PE1 may include a first lower pixel electrode PE1-a and a first upper pixel electrode PE1-b.

The first lower pixel electrode PE1-a may be disposed on the insulating layer 130 and may be connected to the switching element T1 through the insulating layer 130. Further, the first lower pixel electrode PE1-a may be electrically connected to the first semiconductor layer SEM1 of the first light emitting element LE1 through the connection electrode 150.

The first upper pixel electrode PE1-b may be disposed on the second light emitting element LE2 and may be connected to the first lower pixel electrode PE1-a through a contact hole penetrating the insulating layer 130.

The first upper pixel electrode PE1-b may include at least one of Li. Ca, LiF/Ca, LiF/Al, Al, Ag, and Mg in an embodiment. The first upper pixel electrode PE1-b may be a transparent or translucent electrode including at least one of indium tin oxide (ITO), indium zinc oxide (IZO), Zinc Oxide (ZnO), Indium, Oxide (In₂O₃), Indium Gallium Oxide (IGO), and Aluminum Zinc Oxide (AZO). The first lower pixel electrode PE1-a and the first upper pixel electrode PE1-b may include a same material, but the disclosure is not limited thereto, and the first lower pixel electrode PE1-a may include a metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Further, the first lower pixel electrode PE1-a may have a multilayer structure in which two or more metal layers are stacked. For example, the first lower pixel electrode PE1-a may have a double layer structure with a copper layer stacked on top of a titanium layer, but the disclosure is not limited thereto.

As such, the first light emitting element LE1 and the second light emitting element LE2 of the first light emitting area EA1 may be supplied with a pixel voltage or an anode voltage from the first pixel electrode PE1 and a common voltage through the first common electrode CE1. The first light emitting element LE1 and the second light emitting element LE2 may emit light at a luminance according to a voltage difference between the pixel voltage and the common voltage.

Referring to FIGS. 7 and 8, the light emitting element part LEP of the first light emitting area EA1 has been described. Similarly, the second light emitting area EA2 and the third light emitting area EA3 may also be formed with light emitting element parts LEP. For example, the third light emitting element LE3 and the fourth light emitting element LE4 of the second light emitting area EA2 may be supplied with the pixel voltage or the anode voltage from the second pixel electrode PE2 and the common voltage through the second common electrode CE2. The third light emitting element LE3 and the fourth light emitting element LE4 may emit light at a luminance depending on a voltage difference between the pixel voltage and the common voltage. Furthermore, the fifth light emitting element LE5 and the sixth light emitting element LE6 of the third light emitting area EA3 may be supplied with the pixel voltage or the anode voltage from the third pixel electrode PE3 and the common voltage through the third common electrode CE3. The fifth light emitting element LE5 and the sixth light emitting element LE6 may emit light at a luminance according to a voltage difference between the pixel voltage and the common voltage.

Hereinafter, the manufacturing process of the display device 10 according to an embodiment will be described with reference to the drawings.

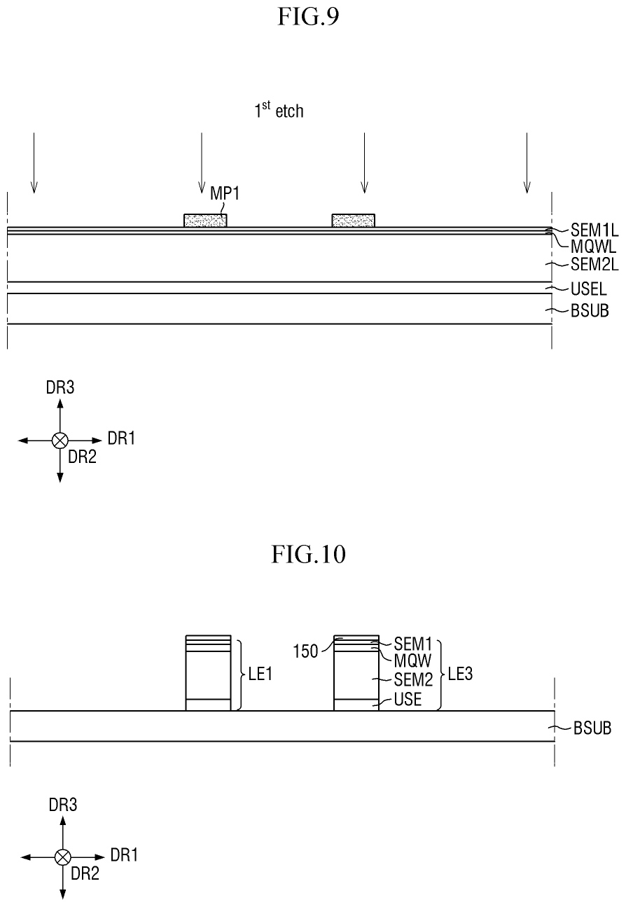

FIGS. 9 to 31 are schematic diagrams for explaining a method of manufacturing a display device according to an embodiment. FIGS. 9 to 31 illustrate the structure of each layer of the light emitting element and display substrate 100 in the order of formation, in cross-sectional and plan view. In FIGS. 9 to 31, the manufacturing process of the light emitting element layer LPL is illustrated, and these may generally correspond to the cross-sectional views of FIGS. 6 to 8.

Referring to FIGS. 9 and 10, the light emitting elements LE may be formed on a base substrate BSUB.

For example, the base substrate BSUB may be prepared. The base substrate BSUB may be a sapphire substrate Al₂O₃ or a silicon wafer including silicon. However, the disclosure is not limited thereto, and in an embodiment, an embodiment where the base substrate BSUB is a sapphire substrate will be described.

Multiple semiconductor material layers USEL, SEM2L, MQWL, and SEM1L may be formed on the base substrate BSUB. The semiconductor material layers grown by an epitaxial method may be formed by growing a seed crystal. Methods for forming semiconductor material layers may include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like. For example, the semiconductor material layers may be formed by metal organic chemical vapor deposition (MOCVD). However, the disclosure is not limited thereto.

A precursor material for forming the semiconductor material layers is not particularly limited within the range that may be conventionally selected for forming the subject material. In an embodiment, the precursor material may be a metal precursor including an alkyl group such as a methyl or ethyl group. For example, the precursor material may be a compound such as trimethyl gallium (Ga(CH₃)₃), trimethyl aluminum (Al(CH₃)₃), and triethyl phosphate ((C₂H₅)₃PO₄), but the disclosure is not limited thereto.

For example, a third semiconductor material layer USEL may be formed on the base substrate BSUB. While the drawings illustrate the third semiconductor material layer USEL being further stacked, the disclosure is not limited thereto, and multiple layers may be formed. The third semiconductor material layer USEL may be disposed to reduce a lattice constant difference between a second semiconductor material layer SEM2L and the base substrate BSUB. For example, the third semiconductor material layer USEL may include an undoped semiconductor, which may be an n-type or p-type undoped material. In an embodiment, the third semiconductor material layer USEL may be at least one of undoped InAlGaN, GaN, AlGaN, InGaN, AlN, and InN, but the disclosure is not limited thereto.

The second semiconductor material layer SEM2L, the active material layer MQWL, and the first semiconductor material layer SEM1L may be sequentially formed on the third semiconductor material layer USEL by using the above-described method.

The semiconductor material layers USEL, SEM2L, MQWL, and SEM1L may be etched to form the light emitting elements LE1 and LE3.

For example, multiple first mask patterns MP1 may be formed on the first semiconductor material layer SEM1L. The first mask pattern MP1 may be a hard mask including an inorganic material or a photoresist mask including an organic material. The first mask pattern MP1 may prevent the semiconductor material layers USEL, SEM2L, MQWL, and SEM1L under the first mask pattern MP1 from being etched. A portion of the semiconductor material layers may be etched (1^{st} etch) using the first mask patterns MP1 as a mask to form the light emitting elements LE1 and LE3.

As shown in FIG. 10, on the base substrate BSUB, the semiconductor material layers USEL, SEM2L, MQWL, and SEM1L that are non-overlapping the first mask pattern MP1 may be etched and removed, and the portions that are not etched overlapping the first mask pattern MP1 may be formed into the light emitting elements LE1 and LE3.

The semiconductor material layers may be etched by conventional methods. For example, the process of etching the semiconductor material layers may be dry etching, wet etching, reactive ion etching (RIE), deep reactive ion etching (DRIE), inductively coupled plasma reactive ion etching (ICP-RIE), or the like. In the case of dry etching methods, anisotropic etching is possible, which may be suitable for vertical etching. When utilizing the etching method described above, the etchant may be Cl₂ or O₂. However, the disclosure is not limited thereto.

The semiconductor material layers USEL, SEM2L, MQWL, and SEM1L overlapping the first mask pattern MP1 in a plan view may be not etched but may be formed into the light emitting elements LE. Thus, the light emitting elements LE may be formed including a third semiconductor layer USE, the second semiconductor layer SEM2, the active layer MQW, and the first semiconductor layer SEM1.

The connection electrode 150 may be formed on the first semiconductor layer SEM1 of the light emitting element LE.

The connection electrode 150 may be formed on the first semiconductor layer SEM1 by depositing a layer of electrode material on the base substrate BSUB and etching the layer of electrode material using an etching process to form the connection electrode 150 on the first semiconductor layer SEM1. The connection electrode 150 may include a reflective layer and a connection layer, although not shown.

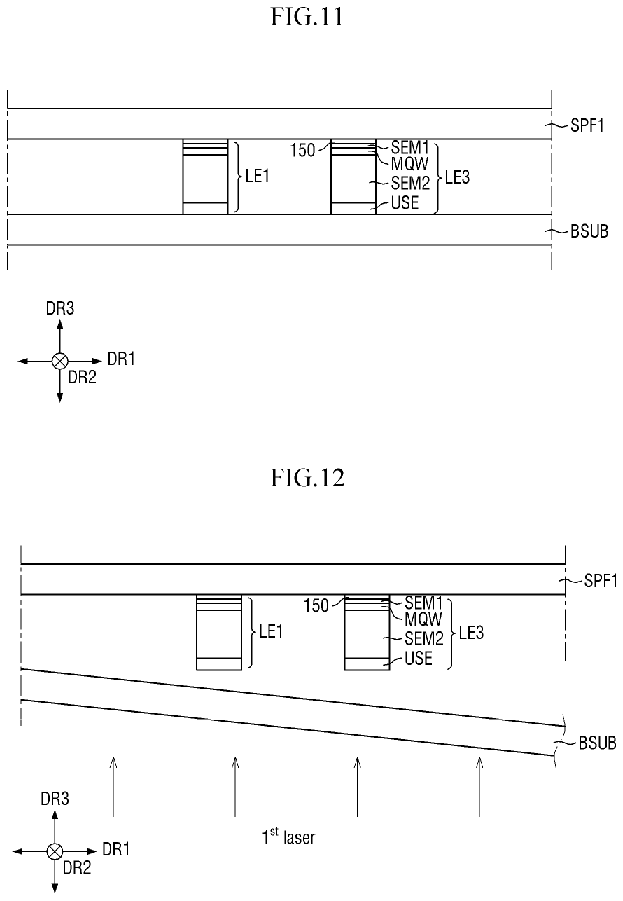

Referring to FIG. 11, a first support film SPF1 may be attached to the light emitting elements LE1 and LE3 on the base substrate BSUB manufactured in FIG. 10.

For example, the first support film SPF1 may be attached to the light emitting elements LE1 and LE3. The first support film SPF1 may be aligned on the light emitting elements LE1 and LE3, and attached to each of the connection electrodes 150 of the light emitting elements LE1 and LE3. The light emitting elements LE1 and LE3 may be arranged in a large number, so that light emitting elements may be attached to the first support film SPF1 without being detached.

The first support film SPF1 may comprise a support layer and an adhesive layer disposed on the support layer. The support layer may be made of a transparent, mechanically stable material that allows light to penetrate. For example, the support layer may include a transparent polymer such as polyester, polyacrylic, polyepoxy, polyethylene, polystyrene, polyethylene terephthalate, or the like. The adhesive layer may include an adhesive material for bonding the light emitting element LE. For example, the adhesive material may include urethane acrylate, epoxy acrylate, polyester acrylate, or the like. The adhesive material may be a material its adhesion changes as ultraviolet (UV) light or heat is applied, such that the adhesive layer may be readily separated from the light emitting elements LE1 and LE3.

Referring to FIG. 12, the base substrate BSUB may be irradiated with a first laser to separate the light emitting elements LE1 and LE3 from the base substrate BSUB. The base substrate BSUB may be separated from each third semiconductor layer USE of the light emitting elements LE1 and LE3.

The process for separating the base substrate BSUB may be performed by a laser lift off (LLO) process. The laser lift off process may utilize a laser, and a KrF excimer laser (248 nm wavelength) may be used as a source. The energy density of the excimer laser may be in a range of about 550 550 mJ/cm² to about 950 550 mJ/cm², and the incident area may be in a range of about 50×50 μm² to about 1×1 cm², but the disclosure is not limited thereto. The base substrate BSUB may be separated from the light emitting elements LE1 and LE3 by irradiating the base substrate BSUB with laser.

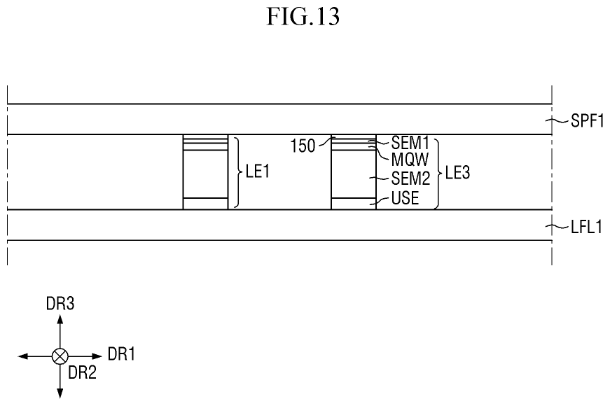

Referring to FIG. 13, a first transfer film LFL1 may be attached to the light emitting elements LE1 and LE3 separated from the base substrate BSUB.

For example, the first transfer film LFL1 may be attached to each of the third semiconductor layers USE of the light emitting elements LE1 and LE3. The first transfer film LFL1 may be aligned on the light emitting elements LE1 and LE3 and attached to each third semiconductor layer USE of the light emitting elements LE1 and LE3.

The first transfer film LFL1 may include a stretchable material. The stretchable material may include, for example, polyolefine, polyvinyl chloride (PVC), elastomeric silicone, elastomeric polyurethane, elastomeric polyisoprene, and the like. The first transfer film LFL1 may also include the support layer and the adhesive layer, similar to the first support film SPF1 described above, to bond and support the light emitting elements LE1 and LE3.

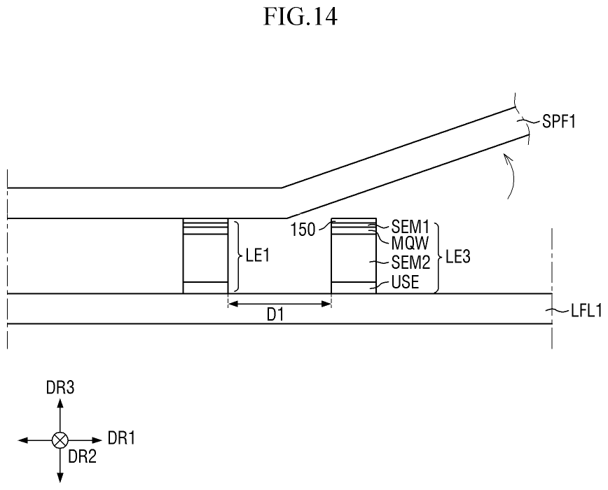

Referring to FIG. 14, the first support film SPF1 may be separated from the light emitting elements LE1 and LE3. The first support film SPF1 may be physically or naturally separated after applying ultraviolet light or heat to the first support film SPF1 to reduce the adhesion of the adhesive layer of the first support film SPF1. The light emitting elements LE1 and LE3 may be disposed on the first transfer film LFL1 spaced apart by a first spacing D1.

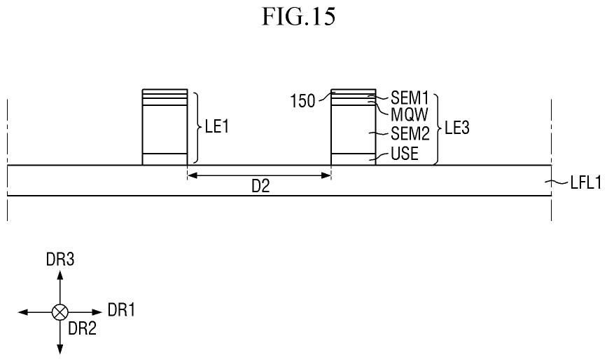

Referring to FIG. 15, the first transfer film LFL1 may be stretched. The first transfer film LFL1 may be stretched in two dimensions, including the first direction DR1 and the second direction DR2. As the first transfer film LFL1 is stretched, the spacing of the light emitting elements LE1 and LE3 bonded on the first transfer film LFL1 may be a second spacing D2 greater than the first spacing D1 in FIG. 14. An elongation strength (or tensile strength) of the first transfer film LFL1 may be adjusted according to the desired spacing of the light emitting elements LE1 and LE3, and may be, for example, about 120 gf/inch. However, the disclosure is not limited thereto.

The embodiment is described using a single stretching process as an example, but the disclosure is not limited thereto. The stretching process may be performed in multiple times.

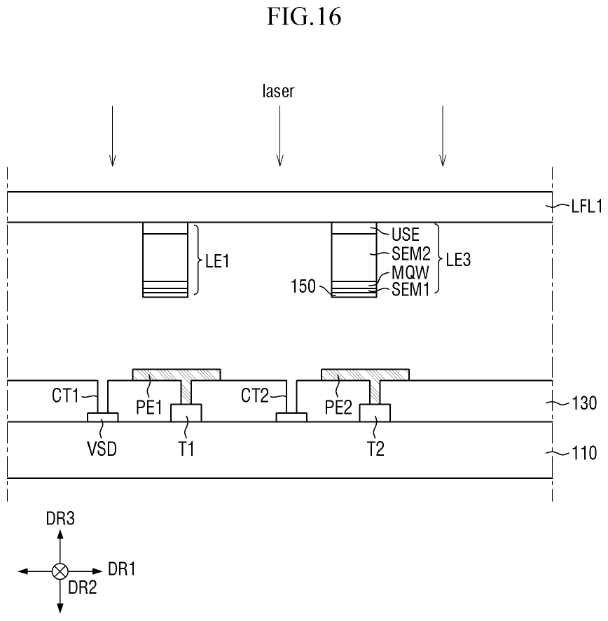

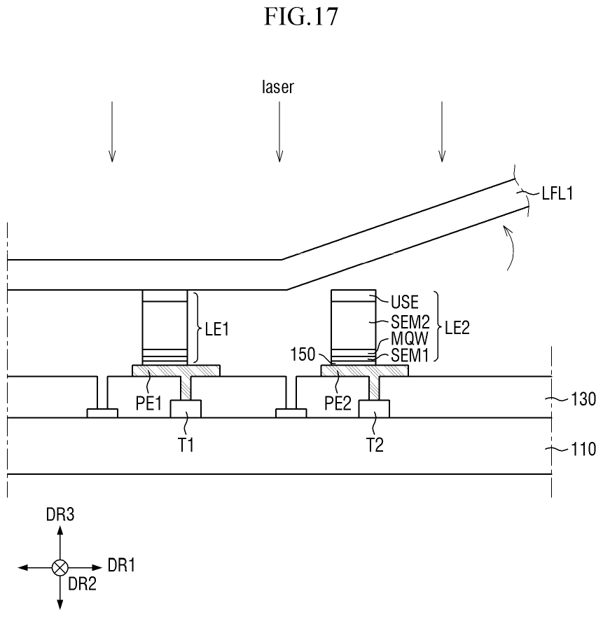

Referring to FIG. 16, the first transfer film LFL1 may be bonded to the first substrate 110 and the light emitting elements LE1 and LE3 may be bonded to the first and second-pixel electrodes PE1 and PE2.

For example, the first transfer film LFL1 may be aligned on the first substrate 110. The connection electrodes 150 of the light emitting elements LE1 and LE3 formed on the first transfer film LFL1 may be aligned to face the first substrate 110. The first substrate 110 may be formed with the pixel electrodes PE1 and PE2, the insulating layer 130, and through holes CT1, CT2, as shown in FIG. 16.

The first substrate 110 and the first transfer film LFL1 may be bonded together. For example, the connection electrodes 150 of the light emitting elements LE1 and LE3 formed on the first transfer film LFL1 may contact the pixel electrodes PE1 and PE2 on the first substrate 110. The connection electrodes 150 of the light emitting elements LE may contact the pixel electrodes PE1 and PE2. The first substrate 110 and the first transfer film LFL1 may be bonded by melting the connection electrodes 150 of the light emitting element LE and the pixel electrodes PE1 and PE2. The light emitting elements LE1 and LE3 may be bonded to the upper surface of the pixel electrodes PE1 and PE2.

As for the melting bonding, a laser may be irradiated onto the pixel electrodes PE1, PE2 from the top of the first transfer film LFL1. A laser transmissive member may be disposed on the first transfer film LFL1, and a laser may be irradiated on the laser transmissive member. The laser-irradiated pixel electrodes PE1 and PE2 may conduct high heat of the laser, and the interface of the connection electrode 150 of the light emitting element LE and the pixel electrodes PE1 and PE2 may be bonded. For example, the pixel electrodes PE1 and PE2 may include copper (Cu), which has excellent thermal conductivity, and may have excellent adhesion properties with the connection electrode 150 of the light emitting element LE. As a source of the laser used for the melting bonding, a YAG may be utilized.

Referring to FIG. 17, the first transfer film LFL1 may be separated from the light emitting elements LE.

For example, the first transfer film LFL1 may be separated from the third semiconductor layer USE of the light emitting elements LE1 and LE3. The process for separating the first transfer film LFL1 may be performed by the laser lift off (LLO) process. The laser lift off process may utilize a laser, and the KrF excimer laser (248nm wavelength) may be used as a source. The energy density of the excimer laser may be in a range of about 550 mJ/cm² to about 950 mJ/cm², and the incident area may be in a range of about 50×50 μm² to about 1×1 cm², but the disclosure is not limited thereto. The second support film SPF2 may be separated from the light emitting elements LE1 and LE3 by irradiating the second support film SPF2 with the laser.

In another embodiment, the process for separating the first transfer film LFL1 may include a physical separation in addition to the laser lift-off process. Since the adhesion force between the first transfer film LFL1 and the light emitting elements LE1 and LE3 is smaller than the melting bonded adhesion force between the connection electrode 150 of the light emitting element LE and the pixel electrodes PE1, PE2, the first transfer film LFL1 may be physically separated based on the adhesion force difference.

In FIG. 17, the third semiconductor layer USE may be removed by an etching process. The third semiconductor layer USE may not have conductivity and may be removed for the connection of the common electrode CE described below.

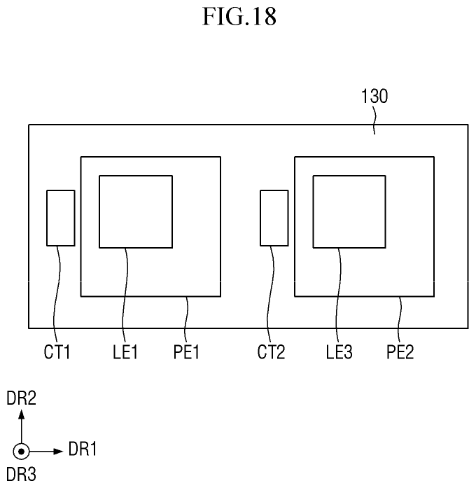

Referring to FIG. 18, the light emitting elements LE1 and LE3 may each disposed on different pixel electrodes PE1 and PE2 on the plane of the display substrate 100 from which the first transfer film LFL1 is separated. Contact holes CT1 and CT2 through the insulating layer 130 may be formed adjacent to the pixel electrodes PE1 and PE2.

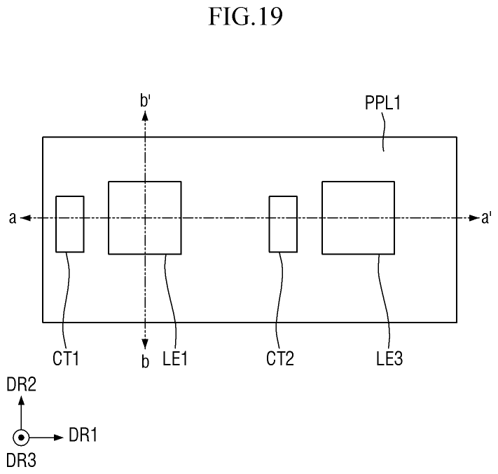

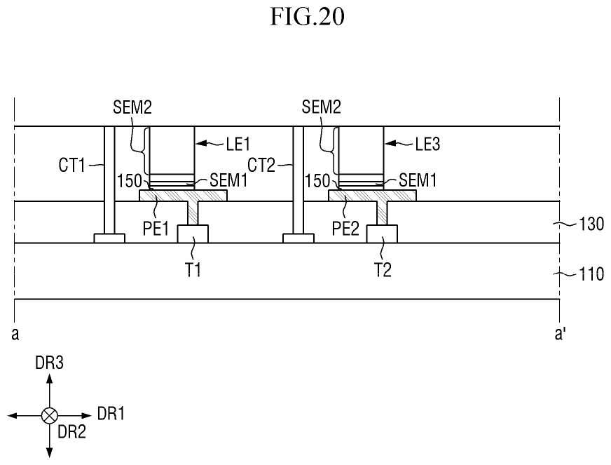

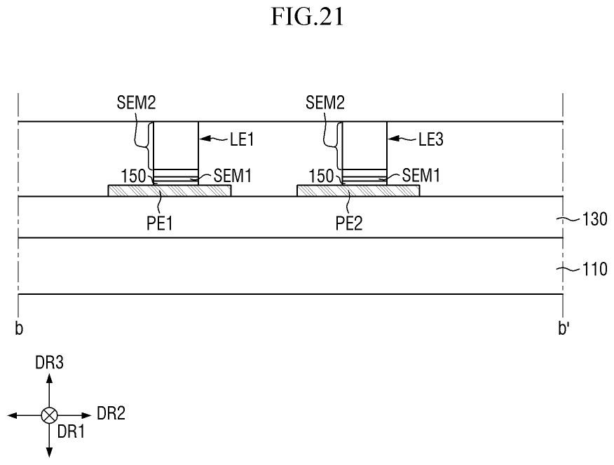

FIG. 19 is a plan view illustrating that a first planarization layer PPL1 is formed on the insulating layer 130 on which multiple light emitting elements LE1 and LE3 are disposed. FIG. 20 is a schematic cross-sectional view taken along a-a′ of FIG. 19, and FIG. 21 is a schematic cross-sectional view taken along b-b′ of FIG. 19.

Referring to FIGS. 19 to 21, an organic material may be applied to the insulating layer 130 on which the light emitting elements LE1 and LE3 are disposed using a solution process such as spin coating or inkjet printing to form the first planarization layer PPL1. The organic material may be formed to completely cover the light emitting elements LE1 and LE3. The organic material may be patterned to form contact holes through the first planarization layer PPL1 to connect with the contact holes CT1 and CT2 through the insulating layer 130. The first planarization layer PPL1 may be patterned through a mask process. The first planarization layer PPL1 may be formed with a height equal to or lower than the height of the second semiconductor layer SEM2 of the light emitting elements LE1 and LE3.

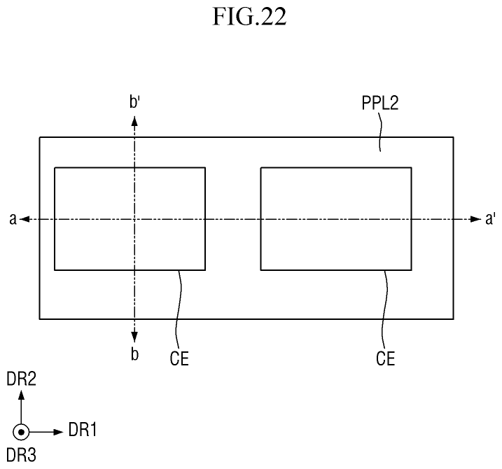

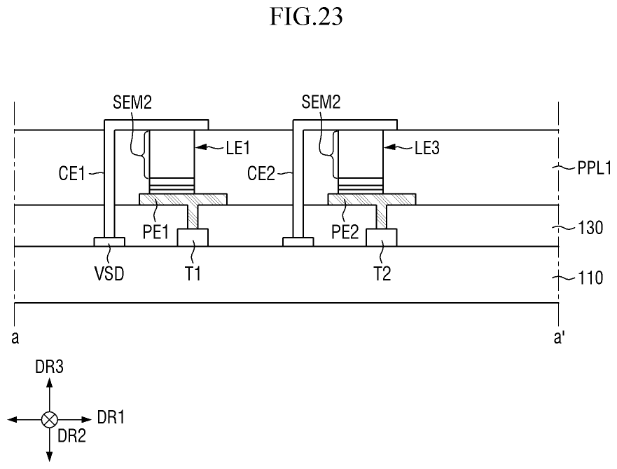

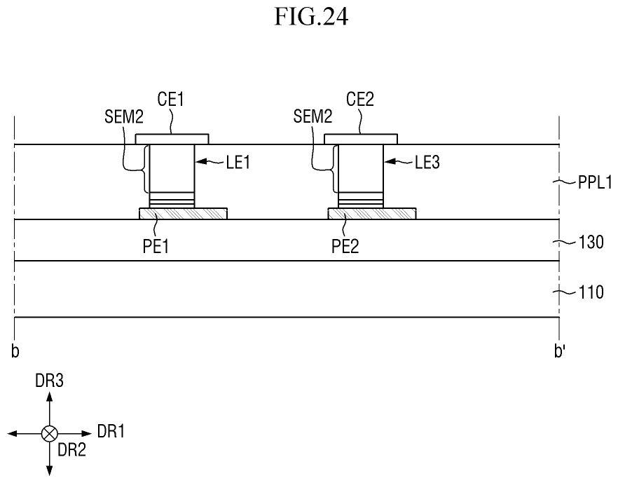

FIG. 22 is a plan view illustrating the common electrode CE1 and CE2 formed on the first planarization layer PPL1. FIG. 23 is a schematic cross-sectional view taken along a-a′ in FIG. 22. FIG. 24 is a schematic cross-sectional view taken along b-b′ in FIG. 22.

The common electrodes CE1 and CE2 may be formed on the light emitting elements LE1 and LE2, and the first planarization layer PPL1. The common electrodes CE1 and CE2 may be formed to cover both the light emitting elements LE1 and LE2 and the contact holes CT1 and CT2 in a plan view. The common electrodes CE1 and CE2 may cover the first planarization layer PPL1 and may be in direct contact with the first planarization layer PPL1. The common electrodes CE1 and CE2 may be formed in direct contact with the top surface of the second semiconductor layer SEM2 of the light emitting elements LE1 and LE2. The common electrodes CE1 and CE2 may be connected to the common voltage pad VSD, which is a conductive pad, through contact holes CT1 and CT2.

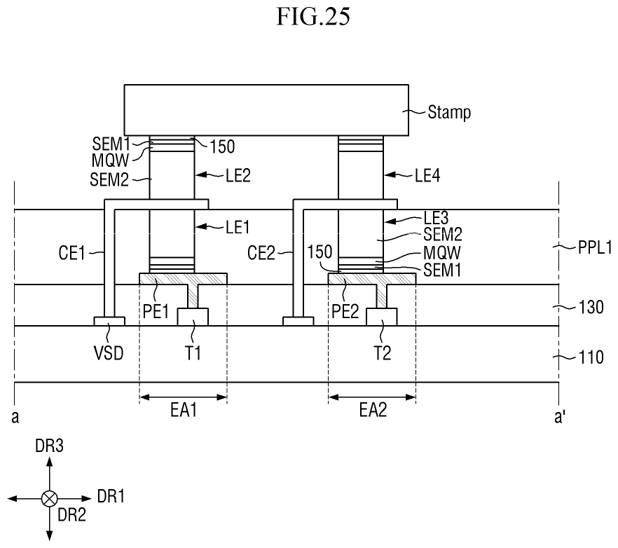

Referring to FIG. 25, multiple light emitting elements LE2 and LE4 may be disposed on the common electrodes CE1 and CE2 using a stamp. The stamp may comprise a support layer and an adhesive layer disposed on the support layer. The support layer may be made of a transparent, mechanically stable material that allows light to pass through. For example, the support layer may include a transparent polymer such as polyester, polyacrylic, polyepoxy, polyethylene, polystyrene, polyethylene terephthalate, or the like. The adhesive layer may include an adhesive material for bonding the light emitting element LE. For example, the adhesive material may include urethane acrylate, epoxy acrylate, polyester acrylate, or the like. The adhesive material may be a material its adhesion changes as ultraviolet (UV) light or heat is applied, such that the adhesive layer may be readily separated from the light emitting elements LE2 and LE4.

The light emitting elements LE2 and LE4 stacked on the growth substrate in the order of the second semiconductor layer SEM2, the active layer MQW, and the first semiconductor layer SEM1 may be transferred onto the common electrodes CE1 and CE2 using the adhesive layer of the stamp. Thus, the second semiconductor layer SEM2, the active layer MQW, and the first semiconductor layer SEM1 may be stacked sequentially from the common electrodes CE1 and CE2. Light emitting elements disposed in the same light emitting area may completely overlap with each other in a plan view. For example, the first light emitting element LE1 and the second light emitting element LE2 disposed in the first light emitting area EA1 may completely overlap with each other in a plan view. Also, the third light emitting element LE3 and the fourth light emitting element L4 disposed in the second light emitting area EA2 may fully overlap with each other in a plan view.

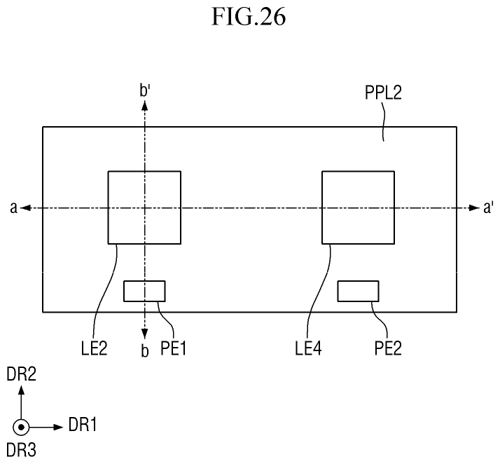

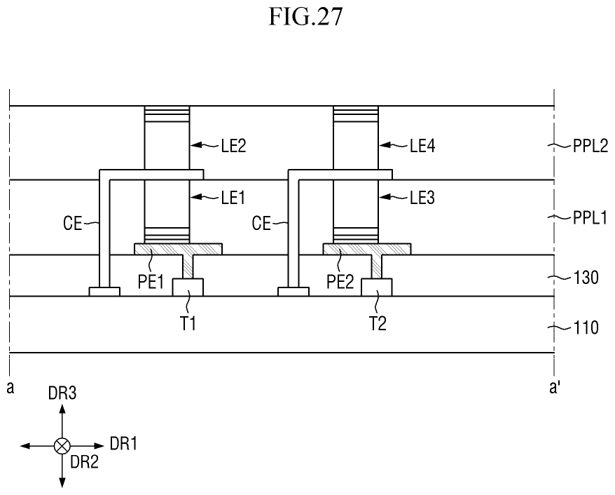

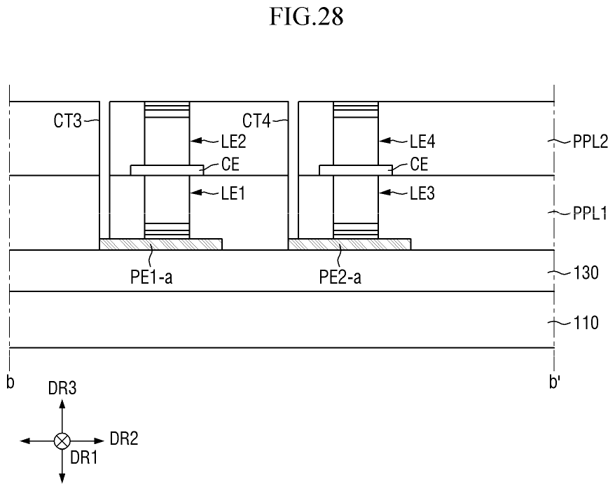

FIG. 26 is a plan view illustrating formation of a second planarization layer PPL2 covering a common electrode CE1 and CE2. FIG. 27 is a schematic cross-sectional view taken along a-a′ of FIG. 26. FIG. 28 is a schematic cross-sectional view taken along b-b′ of FIG. 26.

Referring to FIGS. 26 to 28, an organic material may be applied to the first planarization layer PPL1 on which the light emitting elements LE2 and LE4 are disposed to form the second planarization layer PPL2 using a solution process such as spin coating or inkjet printing. The organic material may be formed to completely cover the light emitting elements LE2 and LE4. The organic material may be patterned to form contact holes CT3 and CT4 through the second planarization layer PPL2 and the first planarization layer PPL1 to connect with the pixel electrodes PE1-a and PE-2-a formed on the insulating layer 130. The pixel electrodes PE1-a and PE-2-a formed on the insulating layer 130 may be referred to as pixel electrodes PE1-a and PE-2-a to distinguish them from the pixel electrodes PE1-b and PE2-b formed on the second planarization layer PPL2 described below. Further, the pixel electrodes PE1-b and PE2-b formed on the second planarization layer PPL2 may be referred to as the upper pixel electrodes PE1-b and PE2-b.

The second planarization layer PPL2 may be patterned by the mask process. The second planarization layer PPL2 may be formed at a height equal to or lower than the height of the second semiconductor layer SEM2 of the light emitting elements LE2 and LE4. Thus, the second planarization layer PPL2 may planarize the step formed by the light emitting elements LE2 and LE4.

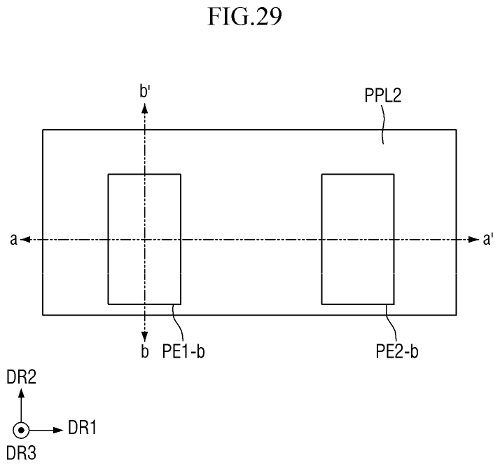

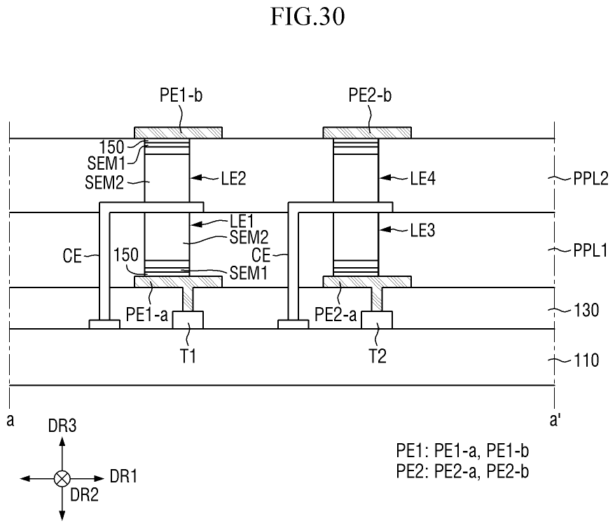

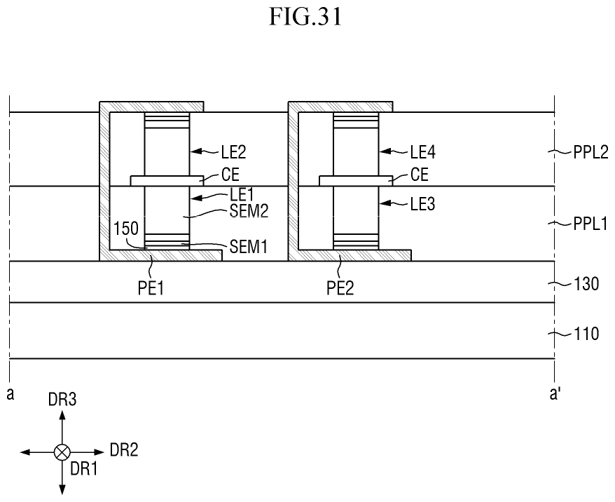

FIG. 29 is a plan view illustrating that the upper pixel electrodes PE1-b and PE2-b are formed on the second planarization layer PPL2. FIG. 30 is a schematic cross-sectional view taken along a-a′ of FIG. 29. FIG. 31 is a schematic cross-sectional view taken along b-b′ of FIG. 29.

Referring to FIGS. 29 to 31, the upper pixel electrodes PE1-b and PE2-b may be formed on the light emitting elements LE2 and LE4 and the second planarization layer PPL2. The upper pixel electrodes PE1-b and PE2-b may be formed to cover both the light emitting elements LE2 and LE4 and the contact holes CT3 and CT4 in a plan view. The common electrodes CE1 and CE2 may cover the first planarization layer PPL1 and may be in direct contact with the first planarization layer PPL1. The upper pixel electrodes PE1-b and PE2-b may be formed in direct contact with the upper surface of the connection electrodes 150 of the light emitting elements LE2 and LE4. The upper pixel electrodes PE1-b and PE2-b may be connected to the lower pixel electrodes PE1-a and PE2-a through the contact holes CT3 and CT4.

Accordingly, the first light emitting element LE1 and the second light emitting element LE2, which are disposed in the same light emitting area, may share the first pixel electrode PE1 and the common electrode CE1. Further, the third light emitting element LE3 and the fourth light emitting element LE4 may share the second pixel electrode PE2 and the common electrode CE2.

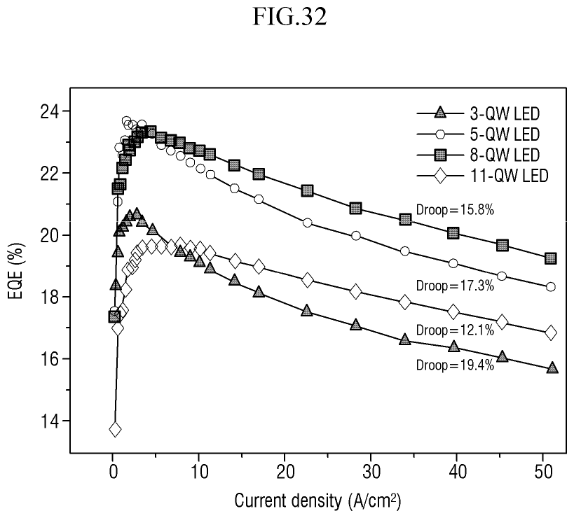

FIG. 32 is a graph illustrating external quantum efficiency as a function of applied current density for parallel-connected light emitting elements according to an embodiment of the disclosure.

Referring to FIG. 32, the external quantum efficiency initially increases with increasing current density and gradually decreases with increasing current density in a phenomenon called efficiency degradation. In case that parallel-connected light emitting elements are applied, the operating point is shifted into the high-efficiency area, as a low-current drive point is obtained.

According to an embodiment, a low-current driving point may be secured by utilizing light emitting elements connected in parallel in one light emitting area.

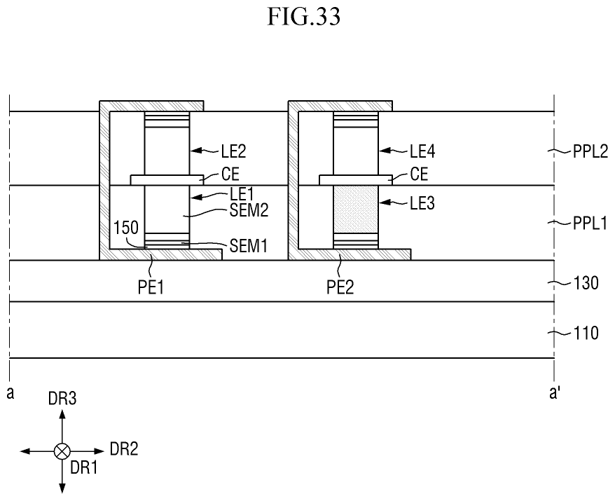

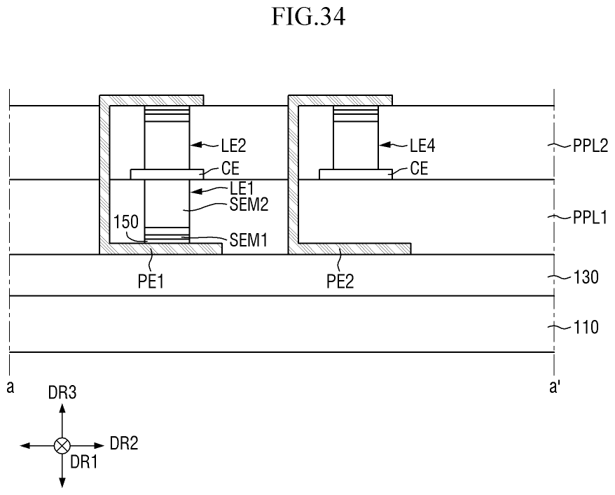

FIGS. 33 and 34 are schematic cross-sectional views of a display substrate according to an embodiment of the disclosure.

As shown in FIGS. 33 and 34, dark spots may be eliminated even in case that one of the light emitting elements connected in parallel in one light emitting area is defective, or in case that the light emitting element is dislodged due to misalignment or the like. For example, even in case that the third light emitting element LE3 is defective or dislodged, the third light emitting element LE4 may operate normally.

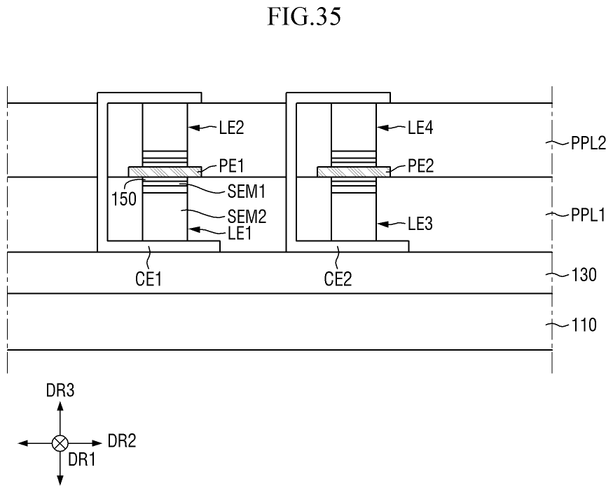

FIGS. 35 to 40 are schematic cross-sectional views of a display substrate according to another embodiment.

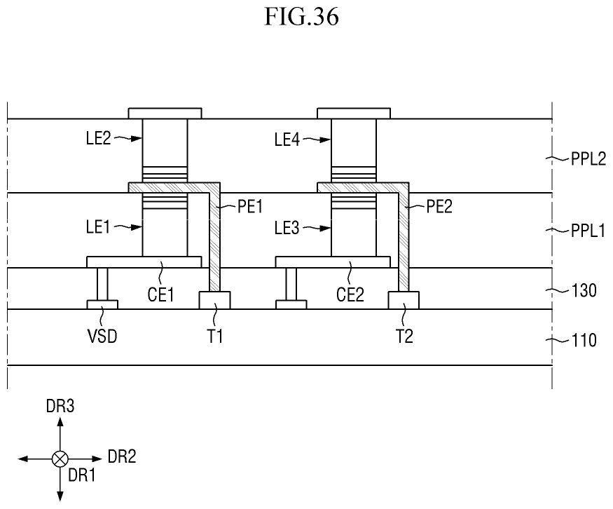

Since FIGS. 35 and 36 differ from the embodiment of FIGS. 6 to 8 only in the stacking direction of the light emitting elements and the arrangement positions of the common electrode and the pixel electrode, the different configurations will be described below focusing on the different configurations.

The common electrode CE1 and CE2 may be formed on the insulating layer 130, the semiconductor layer SEM2, the active layer MQW, the first semiconductor layer SEM1, and the connection electrode 150 may be stacked sequentially from the common electrode CE1 to the first light emitting element LE1 and the third light emitting element LE3, and the pixel electrodes PE1 and PE2 may be disposed on the first light emitting element LE1 and the third light emitting element LE3. The pixel electrodes PE1 and PE2 may be connected to the switching element T through the first planarization layer PPL1.

The second light emitting element LE2 and the fourth light emitting element LE4 may be disposed on the pixel electrodes PE1 and PE2. The second light emitting element LE2 and the fourth light emitting element LE4 may be stacked in the order of the connection electrode 150, the first semiconductor layer SEM1, and the semiconductor layer SEM2 from the pixel electrodes PE1 and PE2. The common electrodes CE1 and CE2 may be disposed on the second semiconductor layer SEM2 of the second light emitting element LE2 and the fourth light emitting element LE4. The common electrodes CE1 and CE2 in contact with the second semiconductor layer SEM2 of the second light emitting element LE2 and the fourth light emitting element LE4 may be connected to the common electrodes CE in contact with the second semiconductor layer SEM2 of the first light emitting element LE1 and the third light emitting element LE3 through a contact hole penetrating the first planarization layer PPL1 and the second planarization layer PPL2.

Thus, the first light emitting element LE1 and the second light emitting element LE2 may share the common electrodes CE1 and CE2 and the pixel electrodes PE1 and PE2.

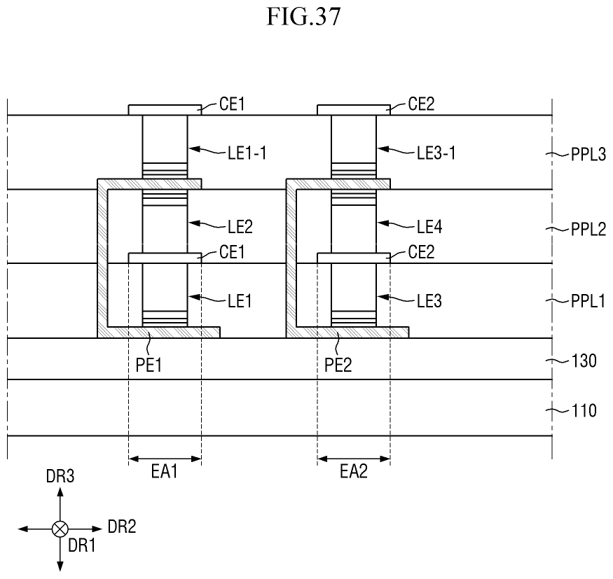

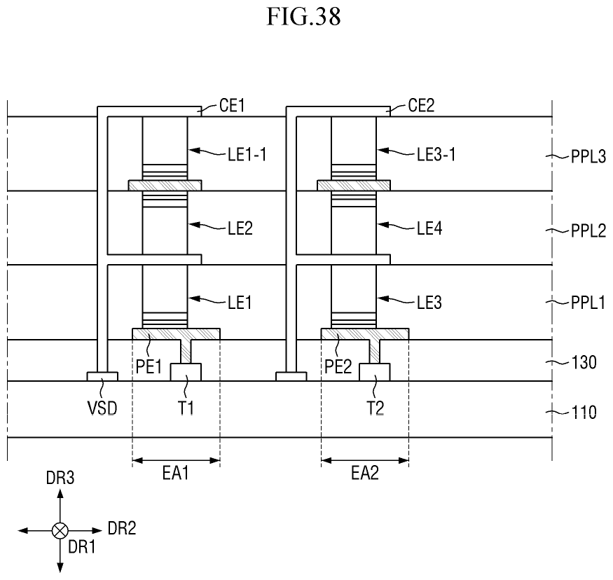

Since FIGS. 37 and 38 differ only in the number of light emitting elements in the embodiment of FIGS. 6 to 8, different configurations will be described below.

Referring to FIGS. 37 and 38, three light emitting elements may be connected in parallel in one light emitting area.

Three light emitting elements LE1, LE2, and LE1-1 may be connected in parallel in the first light emitting area EA1, and three light emitting elements LE3, LE4, and LE3-1 may be connected in parallel in the second light emitting area EA2.

The three light emitting elements LE1, LE2, and LE1-1 disposed in the second light emitting area EA2 may overlap with each other in a plan view.

The light emitting element LE1-1 may be disposed on the second light emitting element LE2 stacked on the first light emitting element LE1 disposed in one light emitting area described in FIGS. 6 to 8. The three light emitting elements LE1, LE2, and LE1-1 disposed in the first light emitting area EA1 may be stacked on top of each other.

The three light emitting elements LE1, LE2, and LE1-1 disposed in the first light emitting area EA1 may share the first common electrode CE1 and the first pixel electrode PE1.

The first common electrode CE1 disposed in contact with the second semiconductor layer SEM2 of each of the three light emitting elements LE1, LE2, and LE1-1 disposed in the first light emitting area EA1 may be connected to each other through a contact hole penetrating the first planarization layer PPL1, the second planarization layer PPL2, and the third planarization layer PPL3. Similarly, the second common electrode CE2 disposed in contact with the second semiconductor layer SEM2 of each of the three light emitting elements LE3, LE4, and LE3-1 disposed in the second light emitting area EA2 may be connected to each other through a contact hole penetrating the first planarization layer PPL1, the second planarization layer PPL2, and the third planarization layer PPL3.

The first pixel electrode PE1 disposed in contact with the connection electrode 150 of each of the three light emitting elements LE1, LE2, and LE1-1 disposed in the first light emitting area EA1 may be connected to each other through a contact hole penetrating the first planarization layer PPL1, the second planarization layer PPL2, and the third planarization layer PPL3. Similarly, the second pixel electrode PE2 disposed in contact with the connection electrode 150 of each of the three light emitting elements LE3, LE4, and LE3-1 disposed in the second light emitting area EA2 may be connected to each other through a contact hole penetrating the first planarization layer PPL1 and the second planarization layer PPL2.

Further, the pixel electrodes PE1 and PE2 may be connected to the switching element T1 through a contact hole penetrating the planarization layers PPL1 and PPL2.

The light emitting elements LE1, LE2, and LE1-1 disposed in the same light emitting area may emit light of a same wavelength band, for example, light of blue wavelength band or a second light, for example, light of green wavelength band. Light emitting elements disposed in different light emitting areas, for example, the first light emitting element LE1 in the first light emitting area EA1 and the second light emitting element LE2 in the second light emitting area EA2, may emit light of different wavelength bands.

In other embodiments, the same layer of different light emitting areas, for example, the first light emitting element LE1 of the first light emitting area EA1 and the second light emitting element LE2 of the second light emitting area EA2, may emit light of a same wavelength, and different layers of the same light emitting area, for example, the first light emitting element LE1 of the first light emitting area EA1, the second light emitting element LE2, and the light emitting elements LE1-1 may emit light of different wavelengths. In case that the first light emitting element LE1, the second light emitting element LE2, and the light emitting element LE1-1 of the first light emitting area EA1 emit light of different wavelengths, the first light emitting area EA1 may emit white light by the light emitting elements LE1, LE2, and LE1-1 connected in parallel. The second light emitting area EA2 is similar, so a detailed description is omitted.

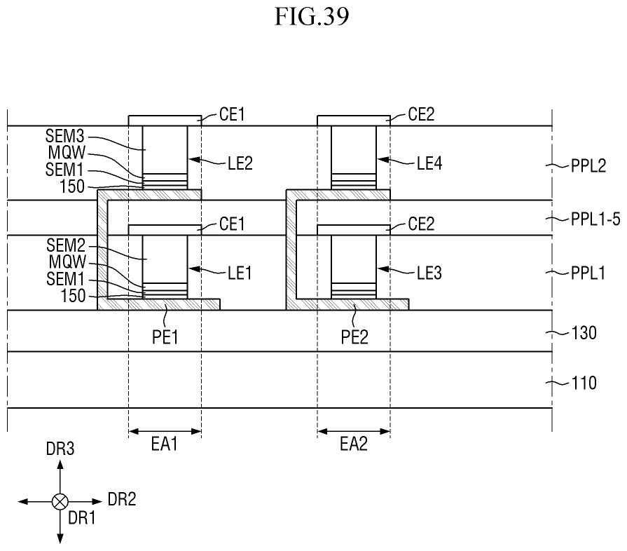

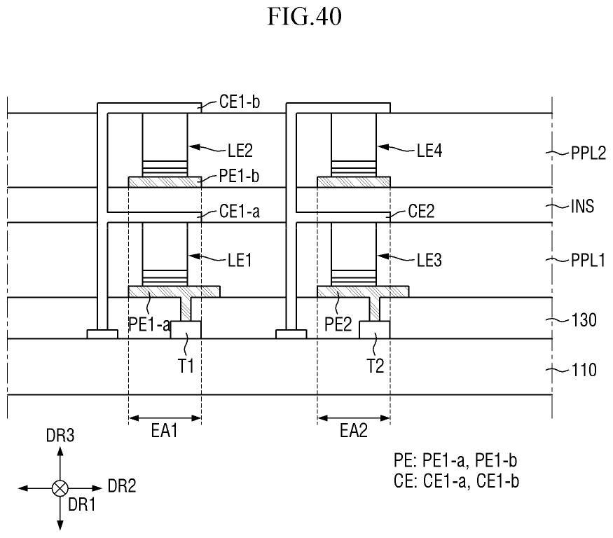

Referring to FIGS. 39 and 40, the light emitting elements LE1, LE2 stacked in one light emitting area may be connected in series with each other, and the light emitting elements LE1 and LE2 stacked in one light emitting area may share the common electrode CE1 and the pixel electrode PE1. For this purpose, the first pixel electrode PE1 may include the first lower pixel electrode PE1-a and the first upper pixel electrode PE1-b. The first lower pixel electrode PE1-a may be disposed on the insulating layer 130 and may be connected to the switching element T1 through a contact hole penetrating the insulating layer 130. The common electrode CE1 may also include a first lower common electrode CE1-a and a first upper common electrode CE1-b. The first lower common electrode CE1-a may be connected to the common voltage pad VSD through a contact hole penetrating the insulating layer 130 and the first planarization layer PPL1.

For example, the first light emitting element LE1 of the first light emitting area EA1 may be stacked on the first lower pixel electrode PE1-a followed by the connection electrode 150, the first semiconductor layer SEM1, the active layer MQW1, and the second semiconductor layer SEM2. The first common electrode CE1 may be disposed on the second semiconductor layer SEM2. An interlayer insulating layer INS may be disposed on the first common electrode CE1. The interlayer insulating layer INS may include an inorganic insulating material such as silicon oxide, silicon nitride, silicon oxynitride, hafnium oxide, aluminum oxide, titanium oxide, tantalum oxide, zinc oxide, and the like, but the disclosure is not limited thereto.

The first upper pixel electrode PE1-b may be disposed on the interlayer insulating layer INS. The first upper pixel electrode PE1-b may be connected to the lower pixel electrode PE1-a through a contact hole penetrating the interlayer insulating layer INS and the first planarization layer PPL1.

The second light emitting element LE2 may be disposed on the first upper pixel electrode PE1-b. The second light emitting element LE2 may be arranged to be aligned with the first light emitting element LE1.

The second light emitting element LE2 may be stacked on the first upper pixel electrode PE1-b in the order of the connection electrode 150, the first semiconductor layer SEM1, the active layer MQW1, and the second semiconductor layer SEM2. The first upper common electrode CE1-b may be disposed on the second semiconductor layer SEM2. The first upper common electrode CE1-b may be connected to the lower common electrode CE1-a through a contact hole penetrating the second planarization layer PPL2.

The display device according to an embodiment may include multiple layers of light emitting elements, and the pixel electrodes and common electrodes of the multiple layers of light emitting elements may be shared. Thus, the stacking structure of the light emitting elements may be simplified. Furthermore, dark spots caused by defects or misalignment of each light emitting element may be eliminated by forming multiple layers of light emitting elements in a same light emitting area.

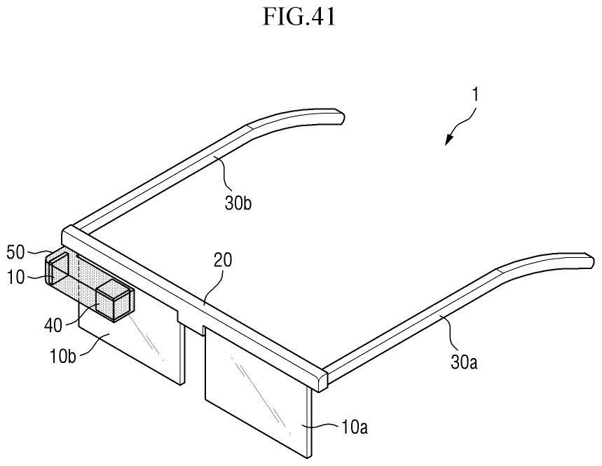

FIG. 41 is a perspective view of a display device according to an embodiment. FIG. 41 illustrates a virtual reality device 1 in which the display device 10 according to an embodiment is used.

Referring to FIG. 41, the virtual reality device 1 according to an embodiment may be a device in a form of glasses. The virtual reality device 1 according to an embodiment may include a display device 10, a left-eye lens 10a, a right-eye lens 10b, a support frame 20, left and right legs 30a and 30b, a reflective member 40, and a display device housing 50.

FIG. 41 schematically illustrates the virtual reality device 1 including the two legs 30a and 30b. However, the disclosure is not limited thereto. The virtual reality device 1 according to an embodiment may be used in a head-mounted display including a head-mounted band that may be mounted on a head instead of the legs 30a and 30b. For example, the virtual reality device 1 according to an embodiment is not be limited to the example shown in FIG. 41, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 41 schematically illustrates that the display device housing 50 is disposed at a right end of the support frame 20. However, the disclosure is not limited thereto. For example, the display device housing 50 may be disposed at a left end of the support frame 20. The image displayed on the display device 10 may be reflected from the reflective member 40 and provided to the user's left eye via the left-eye lens 10a. Thus, the user may view the virtual reality image displayed on the display device 10 via the left eye. In another embodiment, the display device housing 50 may be disposed at each of the left end and the right end of the support frame 20. The user may view the virtual reality image displayed on the display device 10 via both the left eye and the right eye.

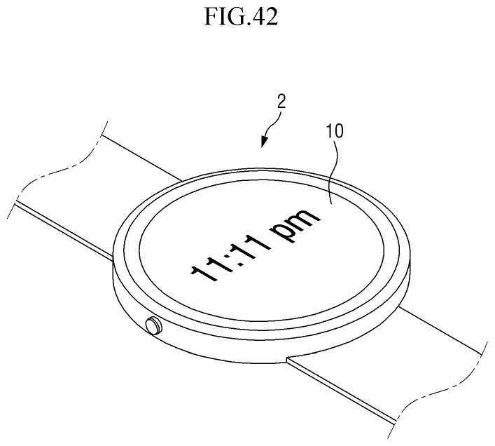

FIG. 42 is a perspective view of a display device according to an embodiment.

Referring to FIG. 42, a display device 10 according to an embodiment may be applied to a smart watch 2 as one of smart devices.

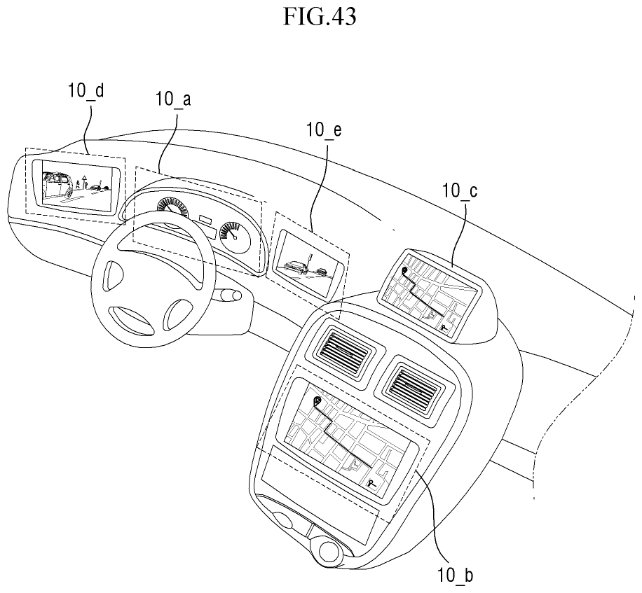

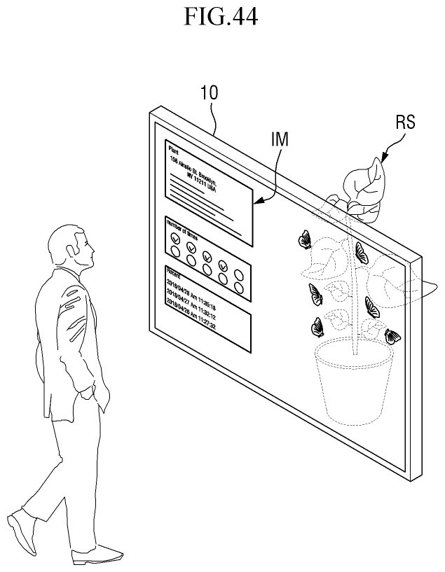

FIG. 43 is a schematic diagram illustrating a vehicle including a display device according to an embodiment. FIG. 43 schematically illustrates a vehicle in which display devices according to an embodiment are used.

Referring to FIG. 43, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle.

FIG. 44 is a perspective view of a transparent display device including a display device according to an embodiment.

Referring to FIG. 44, a display device according to an embodiment may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the first substrate 110 of the display device 10 shown in FIG. 6 may include a light transmitting portion that may transmit light therethrough or may be made of a material that may transmit light therethrough.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first lower electrode disposed on a substrate;
a first light emitting element disposed on the first lower electrode;
a second electrode disposed on the first light emitting element;
a second light emitting element disposed on the second electrode; and
a first upper electrode disposed on the second light emitting element,
wherein the first lower electrode and the first upper electrode are connected to each other.

2. The display device of claim 1, further comprising:
a first planarization layer disposed on the substrate on which the first light emitting element is not disposed; and
a second planarization layer disposed on the first planarization layer on which the second light emitting element is not disposed,
wherein the first lower electrode and the first upper electrode are connected through a contact hole penetrating the first planarization layer and the second planarization layer.

3. The display device of claim 2, wherein
the substrate includes a pixel circuit, and
wherein the first lower electrode and the first upper electrode are connected to the pixel circuit.

4. The display device of claim 1, wherein the first light emitting element and the second light emitting element are connected in parallel.

5. The display device of claim 4, wherein the first light emitting element and the second light emitting element are arranged in opposite directions.

6. The display device of claim 5, wherein
the first light emitting element comprises a first semiconductor layer, an active layer, and a second semiconductor layer sequentially stacked on the first lower electrode, and
the second light emitting element comprises a second semiconductor layer, an active layer, and a first semiconductor layer sequentially stacked on the second electrode.

7. The display device of claim 6, wherein
a surface of the second electrode is in contact with the second semiconductor layer of the first light emitting element, and
another surface corresponding to the one surface of the second electrode is in contact with the second semiconductor layer of the second light emitting element.

8. The display device of claim 6, wherein
the first light emitting element further comprises a connection electrode between the first lower electrode and the first semiconductor layer, and
the second light emitting element further comprises a connection electrode between the first semiconductor layer and the first upper electrode.

9. The display device of claim 3, wherein the first upper electrode comprises a transparent or translucent electrode including at least one of indium tin oxide (ITO), indium zinc oxide (IZO), Zinc Oxide (ZnO), Indium, Oxide (In₂O₃), Indium Gallium Oxide (IGO), and Aluminum Zinc Oxide (AZO).

10. The display device of claim 8, wherein the second electrode comprises a transparent or translucent electrode including at least one of indium tin oxide (ITO), indium zinc oxide (IZO), Zinc Oxide (ZnO), Indium, Oxide (In₂O₃), Indium Gallium Oxide (IGO), and Aluminum Zinc Oxide (AZO).

11. The display device of claim 1, wherein the first light emitting element and the second light emitting element overlap with each other in a thickness direction.

12. The display device of claim 2, wherein
the substrate includes a pixel circuit, and
the second electrode passes through the first planarization layer and is connected to the pixel circuit.

13. The display device of claim 12, wherein
the first light emitting element comprises a second semiconductor layer, an active layer, and a first semiconductor layer sequentially stacked on the first lower electrode, and
the second light emitting element comprises a first semiconductor layer, an active layer, and a second semiconductor layer sequentially stacked on the second electrode.

14. A display device comprising:
a first lower electrode disposed on a substrate;
a first light emitting element disposed on the first lower electrode;
a second lower electrode disposed on the first light emitting element;
an insulating layer disposed on the second lower electrode;
a first upper electrode disposed on the insulating layer;
a second light emitting element disposed on the first upper electrode; and
a second upper electrode disposed on the second light emitting element, wherein
the first lower electrode and the first upper electrode are connected to each other, and
the second lower electrode and the second upper electrode are connected to each other.

15. The display device of claim 14, further comprising:
a first planarization layer disposed on the substrate on which the first light emitting element is not disposed; and
a second planarization layer disposed on the insulating layer on which the second light emitting element is not disposed, wherein
the first lower electrode and the first upper electrode are connected through a contact hole penetrating the first planarization layer and the insulating layer, and
the second lower electrode and the second upper electrode are connected through a second contact hole penetrating the second planarization layer and the second insulating layer.

16. The display device of claim 14, wherein the first light emitting element and the second light emitting element are connected in series.

17. A display device comprising:
a first lower electrode disposed on a substrate;
a first light emitting element disposed on the first lower electrode;
a second lower electrode disposed on the first light emitting element;
a second light emitting element disposed on the second lower electrode;
a first upper electrode disposed on the second light emitting element;
a third light emitting element disposed on the first upper electrode; and
a second upper electrode disposed on the third light emitting element, wherein
the first lower electrode and the first upper electrode are connected to each other, and
the second lower electrode and the second upper electrode are connected to each other.

18. The display device of claim 17, further comprising:
a first planarization layer disposed on the substrate on which the first light emitting element is not disposed;
a second planarization layer disposed on the first planarization layer on which the second light emitting element is not disposed; and
a third planarization layer disposed on the second planarization layer on which the third light emitting element is not disposed, wherein
the first lower electrode and the first upper electrode are connected through a contact hole penetrating the first planarization layer and the second planarization layer, and
the second lower electrode and the second upper electrode are connected through a second contact hole penetrating the third planarization layer and the second planarization layer.

19. The display device of claim 18, wherein the first light emitting element, the second light emitting element, and the third light emitting element are connected in parallel.

20. The display device of claim 19, wherein
the first light emitting element comprises a first semiconductor layer, an active layer, and a second semiconductor layer sequentially stacked on the first lower electrode,
the second light emitting element comprises a second semiconductor layer, an active layer, and a first semiconductor layer sequentially stacked on the second lower electrode, and
the third light emitting element comprises a first semiconductor layer, an active layer, and a second semiconductor layer sequentially stacked on the first upper electrode.
